(19) United States
(12) Patent Application Publication
(10) Pub. No.: US 2014/0220260 A1
(43) Pub. Date: Aug. 7, 2014

(54) SUBSTRATE PROCESSING APPARATUS AND METHOD OF DEPOSITING A FILM

(71) Applicant: Tokyo Electron Limited, Tokyo (JP)

(72) Inventors: Jun Yamawaku, Yamanashi (JP); Chishio Koshimizu, Yamanashi (JP); Mitsuhiro Tachibana, Iwate (JP); Hitoshi Kato, Iwate (JP); Takeshi Kobayashi, Iwate (JP); Shigehiro Miura, Iwate (JP); Takafumi Kimura, Yamanashi (JP)

(73) Assignee: Tokyo Electron Limited, Tokyo (JP)

(21) Appl. No.: 14/171,928

(22) Filed: Feb. 4, 2014

(30) Foreign Application Priority Data
Feb. 6, 2013 (JP) 2013-021384

(51) Int. Cl. C23C 16/50

(52) U.S. Cl. CPC C23C 16/50
USPC 427/569; 118/723 R

(57) ABSTRACT

A substrate processing apparatus for performing a plasma process inside a vacuum chamber includes a turntable including substrate mounting portions for the substrates formed along a peripheral direction of the vacuum chamber to orbitally revolve these; a plasma generating gas supplying portion supplying a plasma generating gas into a plasma generating area; an energy supplying portion supplying energy to the plasma generating gas to change the plasma generating gas to plasma; a bias electrode provided on a lower side of the turntable to face the plasma generating area and leads ions in the plasma onto surfaces of the wafers; and an evacuation port evacuating the vacuum chamber, wherein the bias electrode extends from a rotational center of the turntable to an outer edge side, and a width of the bias electrode in a rotational direction is smaller than a distance between adjacent substrate mounting portions.

### CROSS-REFERENCE TO RELATED APPLICATIONS

This patent application is based upon and claims the benefit of priority of Japanese Patent Application No. 2013-021384 filed on Feb. 6, 2013, the entire contents of which are incorporated herein by reference.

### BACKGROUND OF THE INVENTION

1. Field of the Invention

The present invention relates to a substrate processing apparatus which performs a plasma process to a substrate and a method of depositing a film.

2. Description of the Related Art

For example, an atomic layer deposition (ALD) method using an apparatus disclosed in Japanese Laid-open Patent Application No. 2010-239102 is known as a method of depositing a film such as a silicon oxide (SiO₂) film on a substrate (hereinafter, referred to as a “wafer”) such as a semiconductor wafer. In this apparatus, 5 wafers are arranged in the peripheral direction of a turntable on the turntable and a plurality of gas nozzles are arranged on an upper side of the turntable. The wafers orbitally revolve around and a plurality of reaction gases of a plurality of types, which mutually react, are sequentially supplied to the wafers to thereby deposit a reaction product on the wafers.

As to the ALD method, Japanese Laid-open Patent Publication No. 2011-40574 discloses an apparatus having a member for performing plasma reformulation at separated positions in the peripheral direction relative to the a gas nozzle in order to perform the plasma reformulation to a reaction product laminated on a wafer. However, if a depressed portion such as a hole or a groove (e.g., a trench) having a great aspect ratio exceeding several tens or several hundreds is formed on the surface of a wafer, a degree of reformulation is not uniform in the depth direction of the depressed portion.

Said differently, if the depressed portion having the great aspect ratio is formed, it is difficult for plasma (e.g., an argon ion) to enter inside the recesses portion. Further, a process of depositing a film is performed along with the plasma reformulation process inside a vacuum chamber. Therefore, the process pressure inside the vacuum chamber is high in comparison with the vacuum atmosphere where plasma can finely maintain its activity. When plasma contacts the inner wall surface of the depressed portion, the plasma is apt to deactivate. Therefore, a degree of reformulation in the depth direction of the depressed portion is apt to be not uniform. Further, in order to perform reformulation for a wafer without a depressed portion while the turntable rotates one turn and in order to perform good reformulation in a narrow area between mutually adjacent gas nozzles, it is necessary to form plasma having a high density in the vicinity of the wafer. Japanese Laid-open Patent Publication No. 6-213378 discloses an apparatus where a bias voltage is applied to a lower electrode but does not disclose a technique where a wafer is orbitally revolved by a turntable.

### SUMMARY OF THE INVENTION

The embodiments of the present invention are provided in consideration of the above situation. The object of the embodiment is to provide a substrate processing apparatus and a method of depositing a film, the substrate processing apparatus and the method being capable of performing a plasma process for a plurality of substrates orbitally revolved by the turntable with high uniformity in the depth direction of a depressed portion on the surface of each substrate.

According to an aspect of the invention, there is provided a substrate processing apparatus for performing a plasma process for substrates inside a vacuum chamber including a turntable which includes substrate mounting portions for mounting the substrates formed at a plurality of positions along a peripheral direction of the vacuum chamber and causes the substrate mounting portions to orbitally revolve around; a plasma generating gas supplying portion which supplies a plasma generating gas into a plasma generating area for performing the plasma process for the substrates; an energy supplying portion which supplies energy to the plasma generating gas in order to change the plasma generating gas to plasma; a bias electrode which is provided on a lower side of the turntable so as to face the plasma generating area and leads ions included in the plasma onto surfaces of the wafers; and an evacuation port which evacuates an inside of the vacuum chamber, wherein the bias electrode is formed so as to extend from a side of a rotational center of the turntable to an outer edge side of the turntable, and a width of the bias electrode in a rotational direction of the turntable is smaller than a distance between adjacent substrate mounting portions included in the substrate mounting portions.

According to another aspect of the invention, there is provided a method of depositing a film of performing process of depositing the film onto substrates inside a vacuum chamber including mounting the substrates on substrate mounting portions formed on the turntable at a plurality of positions along a peripheral direction of the vacuum chamber, surfaces of the substrates being formed with a depressed portion; orbitally revolving the substrate mounting portion around; depositing a molecular layer or an atomic layer on the substrates by supplying a process gas onto the substrates provided on the substrate mounting portions; reformulating the molecular layer or the atomic layer using plasma by supplying a plasma generating gas into a plasma generating area inside the vacuum chamber and changing the plasma generating gas to the plasma; leading ions included in the plasma onto the surfaces of the substrates using a bias electrode located on a lower side of the turntable so as to face the plasma generating area; and evacuating an inside of the vacuum chamber, wherein the bias electrode, used in the leading the ions, is formed so as to extend from a side of a rotational center of the turntable to an outer edge side of the turntable, and a width of the bias electrode in a rotational direction of the turntable is smaller than a distance between adjacent substrate mounting portions included in the substrate mounting portions.

### BRIEF DESCRIPTION OF THE DRAWINGS

FIG. 1 is a vertical cross-sectional view illustrating an exemplary film deposition apparatus of the embodiment of the present invention;

FIG. 2 is a perspective view of the film deposition apparatus;

FIG. 3 is a horizontal cross-sectional plan view of the film deposition apparatus;

FIG. 4 is a horizontal cross-sectional plan view of the film deposition apparatus;

FIG. 5 is a perspective view illustrating a turntable of the film deposition apparatus;

FIG. 6 is an exploded perspective view illustrating a plasma process portion of the film deposition apparatus;

FIG. 7 is an exploded perspective view illustrating a bias electrode of the film deposition apparatus;

FIG. 8 is an enlarged vertical cross-sectional view of a plasma process portion and a bias electrode;

FIG. 9 is a development view of the vertical cross-sectional view of the film deposition apparatus along a peripheral direction of the film deposition apparatus;

FIG. 10 is a horizontal cross-sectional view schematically illustrating a portion where plasma is generated in a case where a bias electrode is formed so as to bridge two wafers;

FIG. 11 is a vertical cross-sectional view schematically illustrating properties of plasma in a case where the bias electrode is formed so as to bridge two wafers;

FIG. 12 is a vertical cross-sectional view schematically illustrating properties of plasma in a case where the bias electrode is formed so as to bridge two wafers;

FIG. 13 is a vertical cross-sectional view schematically illustrating properties of plasma in the embodiment of the present invention;

FIG. 14 is a vertical cross-sectional view schematically illustrating properties of plasma in the embodiment of the present invention;

FIG. 15 is a vertical cross-sectional view schematically illustrating an electric circuit pertinent to the plasma process portion and the bias electrode;

FIG. 16 is a schematic view of the film deposition apparatus for illustrating a function of the film deposition apparatus;

FIG. 17 is a schematic view of the film deposition apparatus for illustrating a function of the film deposition apparatus;

FIG. 18 is a vertical cross-sectional view of schematically illustrating another example of the film deposition apparatus;

FIG. 19 is a vertical cross-sectional view of another example of the film deposition apparatus;

FIG. 20 is a plan view of another example of the film deposition apparatus;

FIG. 21 is a vertical cross-sectional view of another example of the film deposition apparatus;

FIG. 22 is a perspective view of a part of another example of the film deposition apparatus;

FIG. 23 is a horizontal cross-sectional plan view of another example of the film deposition apparatus;

FIG. 24 is a horizontal cross-sectional plan view of another example of the film deposition apparatus;

FIG. 25 is a horizontal cross-sectional plan view of another example of the film deposition apparatus; and

FIG. 26 is a vertical cross-sectional view of another example of the film deposition apparatus.

### DETAILED DESCRIPTION OF EMBODIMENTS

A description is given below, with reference to the figures of the embodiments of the present invention. In the embodiments described below, the reference symbols typically designate as follows:
W: wafer;
1: vacuum chamber;
2: turntable;
P1, P2: process area;
S3: bias space;
10: depressed portion;
31, 32, 34: gas nozzle;
80: plasma process portion;
83: antenna;
95: Faraday shield;
120: bias electrode; and
85, 128: high-frequency power source.

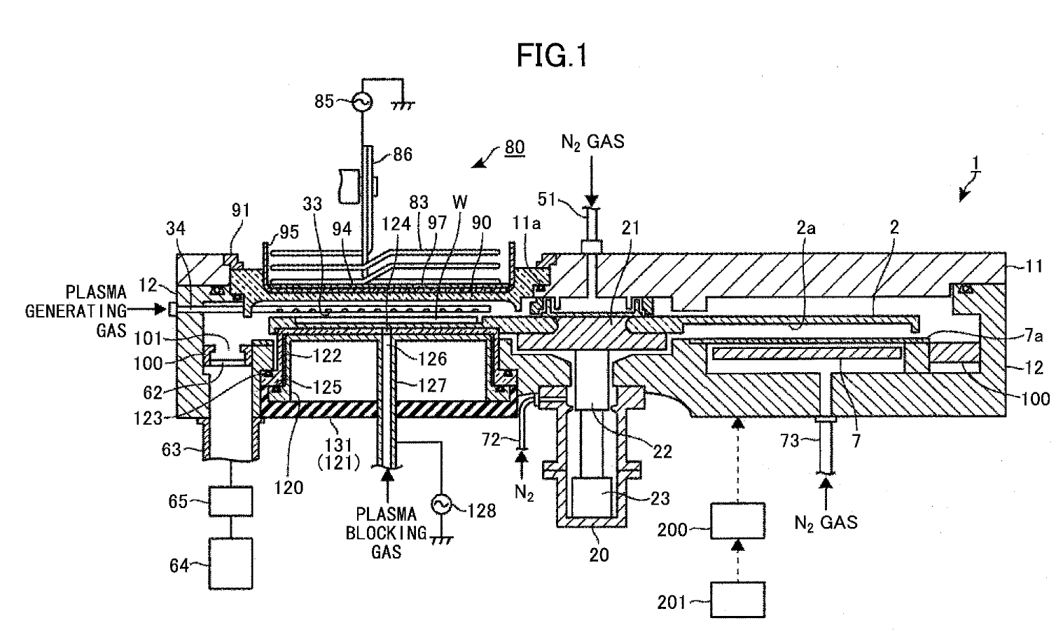

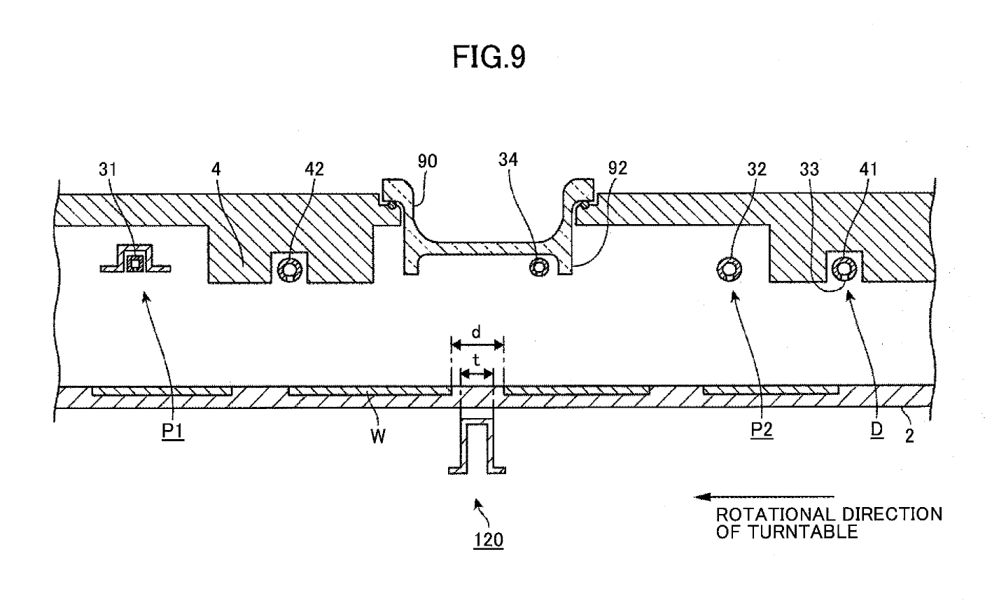

A substrate processing apparatus (a film deposition apparatus) of the embodiment of the present invention is described with reference to FIGS. 1 to 15. Referring to FIGS. 1 to 4, the substrate processing apparatus includes a vacuum chamber 1 having a substantially circular shape in its plan view and a turntable 2 that has the rotational center at the center of the vacuum chamber and causes a plurality of wafers W (e.g., 5 wafers) to orbitally revolve. The substrate processing apparatus is configured to perform a process of depositing the film and a plasma reformulation process for the wafers W. In performing the plasma reformulation process, a bias electrode 120 is arranged on the lower side of the turntable 2 to draw ions in plasma onto the side of the wafer W. Referring to FIG. 9, the width t of the bias electrode 120 in the rotational direction of the turntable 2 is made smaller than the distance d between the wafers W in order to perform the plasma reformulation process with high uniformity among the wafers W adjacently arranged beside each other. Subsequently, a summary of the entire substrate processing apparatus is briefly described before specifically describing the bias electrode 120.

In order to separate process areas P1 and P2 described below, a separation gas supplying pipe 51 for flowing a separation gas (a N₂ gas) into the inside of the vacuum chamber 1 is connected to a central portion of a ceiling plate 11 of the vacuum chamber 1. As illustrated in FIG. 1, a heater unit 7 as a heating mechanism is provided on the lower side of the turntable 2. The heater unit 7 heats the wafers W through the turntable 2 so that the wafers W are heated to be, for example, 300° C. Referring to FIG. 1, a reference symbol 7a designates a cover member and a reference symbol 73 designates a purge gas supplying pipe.

The turntable 2 is made of a dielectric material such as quartz and is fixed to a core portion 21 in a substantially cylindrical shape at the central portion. The turntable 2 is freely rotatable around a rotational shaft (a vertical axis) 22 connected to the lower surface of the core portion 21, for example, in a clockwise direction. Referring to FIG. 1, a driving portion (a rotational mechanism) 23 is provided to rotate the rotational shaft 22 around the vertical axis, and a case body 20 accommodates the rotational shaft 22 and the driving portion 23. A reference symbol 72 designates a purge gas supplying pipe.

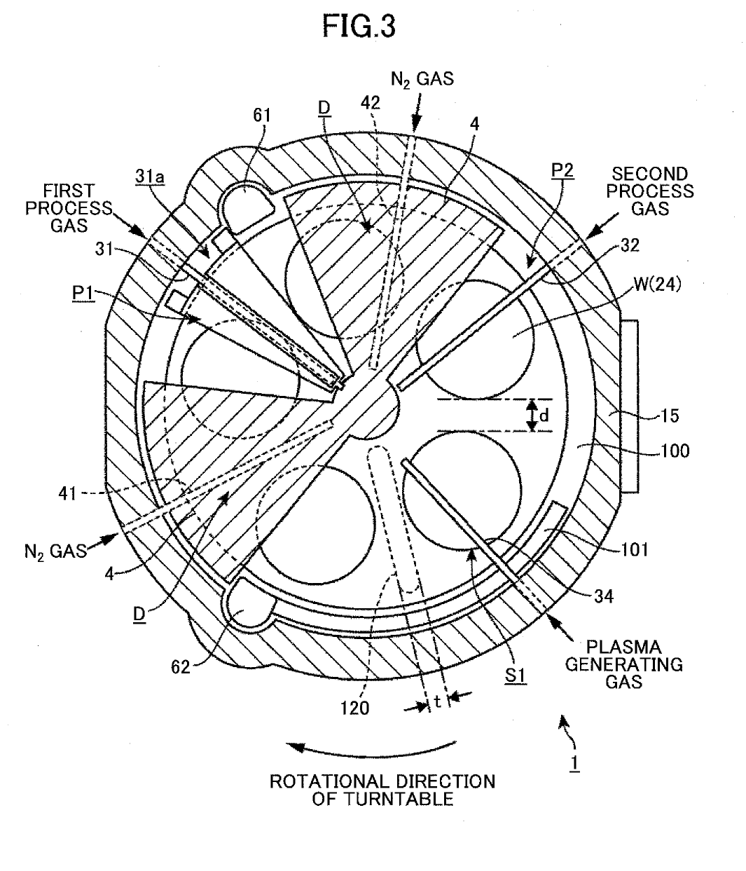

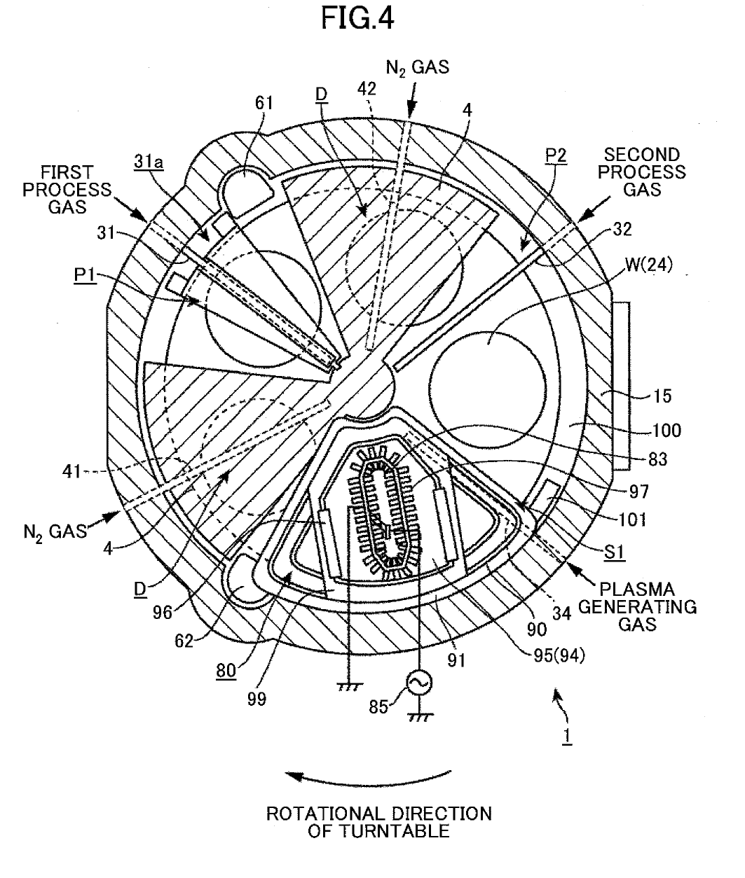

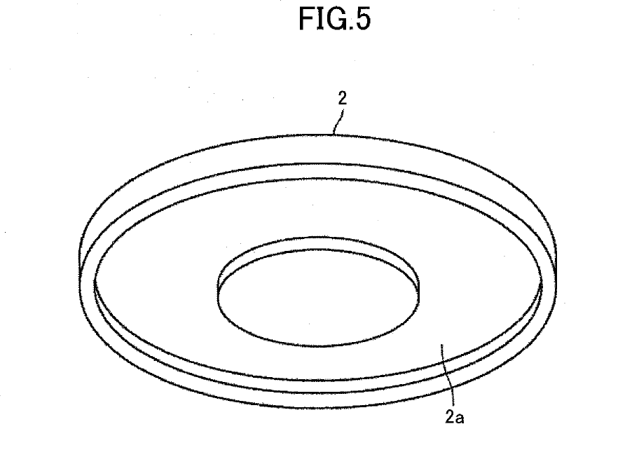

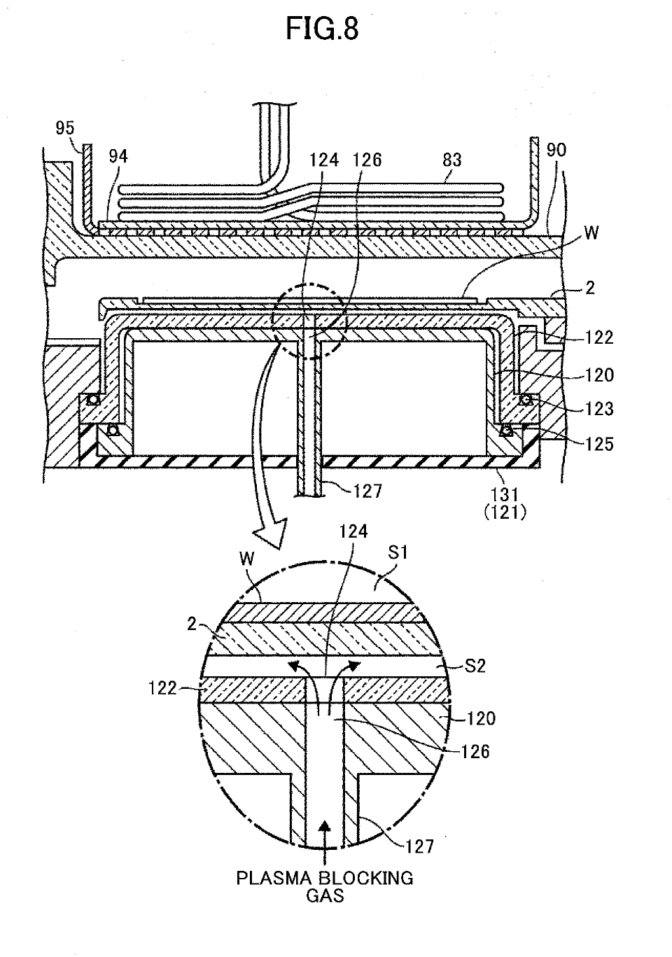

Referring to FIGS. 3 and 4, concave portions 24 as mounting areas for mounting the wafers W are formed on a surface portion of the turntable 2 at a plurality of locations, for example 5 locations, along the rotational direction (a peripheral direction) of the turntable 2. The diameters of the wafers W are, for example, 300 mm. The distance d between the concave portions 24, 24 mutually adjacent to each other in the rotational direction of the turntable 2 is equal to or greater than 30 mm and equal to and less than 120 mm. Referring to FIGS. 5 and 8, a groove portion 2a that is a recess is formed on the lower surface of the turntable 2. The groove portion 2a is recessed like a concentric circle of the turntable 2 (a ring) so that a dimension between the bottom surfaces of the concave portions 24 and the lower surface of the turntable 2 (the thickness of the turntable 2) becomes as small as possible and the groove portion 2a accommodates the bias electrode 120. FIG. 5 is a perspective view of the turntable 2 viewed from the lower side of the turntable 2.

At positions facing a locus area of the concave portions 24 of the turntable 2, five nozzles 31, 32, 34, 41, and 42 are radially arranged while mutually interposing intervals in the peripheral direction of the vacuum chamber 1. For example, these nozzles 31, 32, 34, 41, and 42 are attached to the vacuum chamber 1 so as to horizontally extend from an outer peripheral wall of the vacuum chamber 1 toward the central portion while facing the wafers W. The plasma generating gas nozzle 34, the separation gas nozzle 41, the first processing gas nozzle 31, the separation gas nozzle 42, and the second processing gas 32 are arranged in this order in a clockwise direction (the rotational direction of the turntable 2) from a transfer opening 15 (described below).

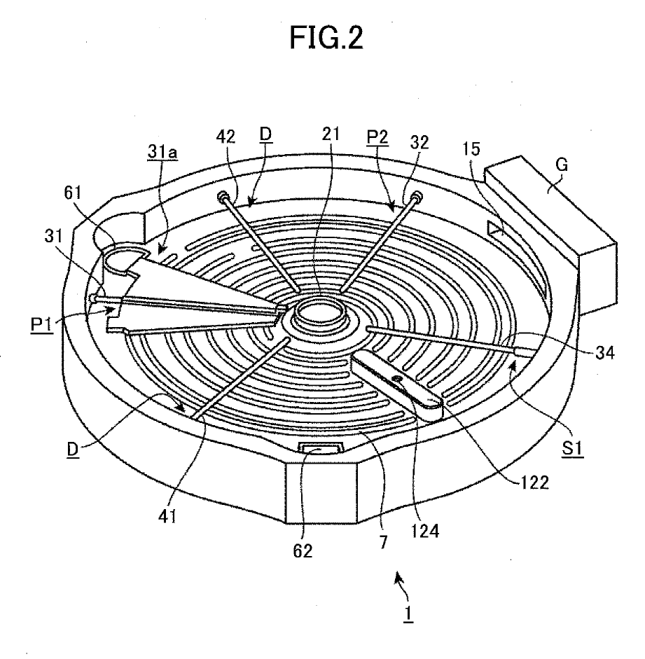

The process gas nozzles 31 and 32 function as a first process gas supplying portion and a second process gas supplying portion, respectively. The plasma generating gas nozzle 34 functions as a plasma generating gas supplying portion. The separation gas nozzles 41 and 42 function as a separating gas supplying portion. Referring to FIGS. 2 and 3, a plasma process portion 80 and a casing 90 (described below) are removed to show the plasma generating gas nozzle 34. Referring to FIG. 4, the plasma process portion 80 and the casing 90 are attached to the vacuum chamber 1. Referring to FIG. 2, the turntable 2 is also removed.

The nozzles 31, 32, 34, 41 and 42 are connected to corresponding gas supplying sources (not illustrated) through flow rate controlling valves. Said differently, the first process gas nozzle 31 is connected to the gas supplying source for supplying a first process gas containing silicon (Si) such as bis(tertiary-butylaminosilane) or a SiH₂(NH-C(CH₃)₃)₂) gas. The second process gas nozzle 32 is connected to a supplying source of the second process gas, for example, a mixed gas containing an ozone (O₃) gas and an oxygen (O₂) gas, specifically, an oxygen gas supplying source having an ozonizer. The plasma generating gas nozzle 34 is connected to a supplying source of the plasma generating gas containing a mixed gas of, for example, an argon (Ar) gas and an oxygen gas. The separation gas nozzles 41 and 42 are connected to corresponding gas supplying sources for supplying a separation gas, namely a N₂ gas. Gas discharging ports 33 are formed on the lower surface sides of the gas nozzles 31, 32, 34, 41, and 42. The gas discharging ports 33 are arranged at an equal interval and at a plurality of locations along a radius direction of the turntable 2. A reference symbol 31a in FIGS. 2 and 3 designate a nozzle cover.

Lower areas below the process gas nozzles 31 and 32 are a first process area (a film deposition area) P1 and a second process area P2. The first process area P1 is provided to cause the first process gas to adsorb onto the wafer W. The second process area P2 is provided to cause the components of the first process gas adsorbing onto the wafer W to react the second process gas. A lower area below the plasma generating gas nozzle 34 is a reformulation area (a plasma generating area) S1 where a plasma reformulation process is performed for the wafers W as described later. The separation gas nozzles 41 and 42 are provided to form separating areas D for separating the first process area P1 and the second process area P2. A ceiling plate 11 of the vacuum chamber 1 has a low ceiling surface as a lower surface of a convex portion 4 positionally corresponding to the separating area D in order to prevent the process gases from mixing.

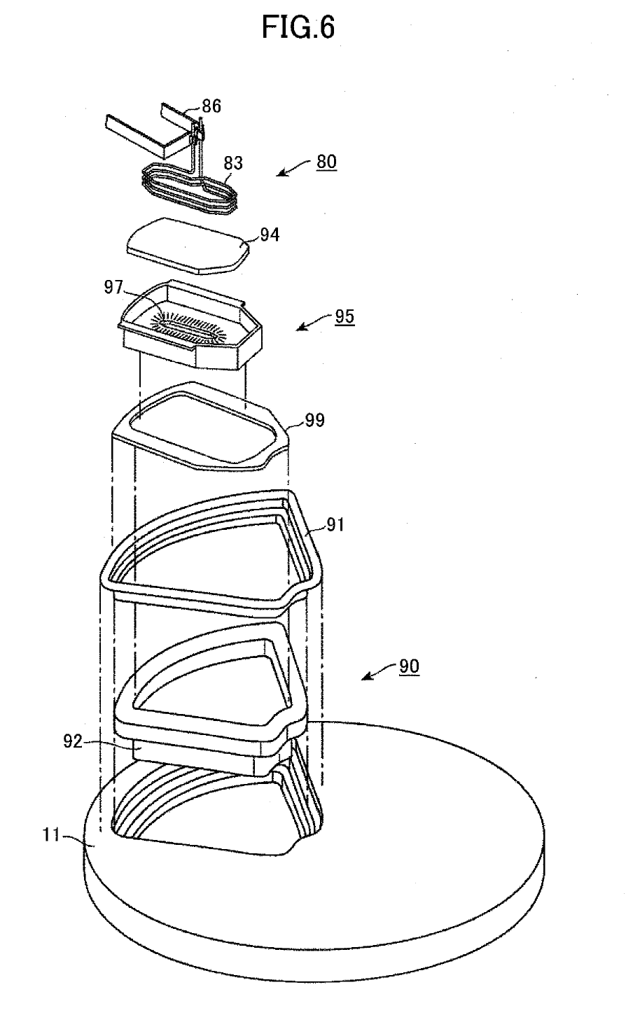

Next, the plasma generating portion 80 is described in detail. Referring to FIGS. 1 and 6, the plasma process portion 80 is formed by winding an antenna 83 made of metal wire around a vertical axis so as to be shaped like a coil. When the plasma process portion 80 is viewed in a plan view, the plasma process portion 80 bridges over the locus area of the wafers W from the center portion side of the turntable 2 to the outer periphery side of the turntable 2. As illustrated in FIG. 4, this antenna 83 is shaped substantially like an octagon and is arranged so as to surround a belt-like area extending along a radius direction of the turntable 2.

The antenna 83 is arranged so as to be hermetically separated from the inner area of the vacuum chamber 1. Said differently, the ceiling plate 11 has an opening having a substantially sector shape in its plan view on the upper side of the plasma generating gas nozzle 34 (described above). As described in FIG. 6, the opening is hermetically sealed by the casing 90 made of a dielectric material such as quartz. The peripheral edge portion of the casing 90 horizontally extends like a flange in the peripheral direction of the casing 90. Further, the central portion of the casing 90 is recessed toward the inner area of the vacuum chamber 1. The antenna 83 is accommodated inside the casing 90. Referring to FIG. 1, a reference symbol 11a designates a sealing member provided between the casing 90 and the ceiling plate 11. A reference symbol 91 designates a pressing member for downward pressing the peripheral edge portion of the casing 90.

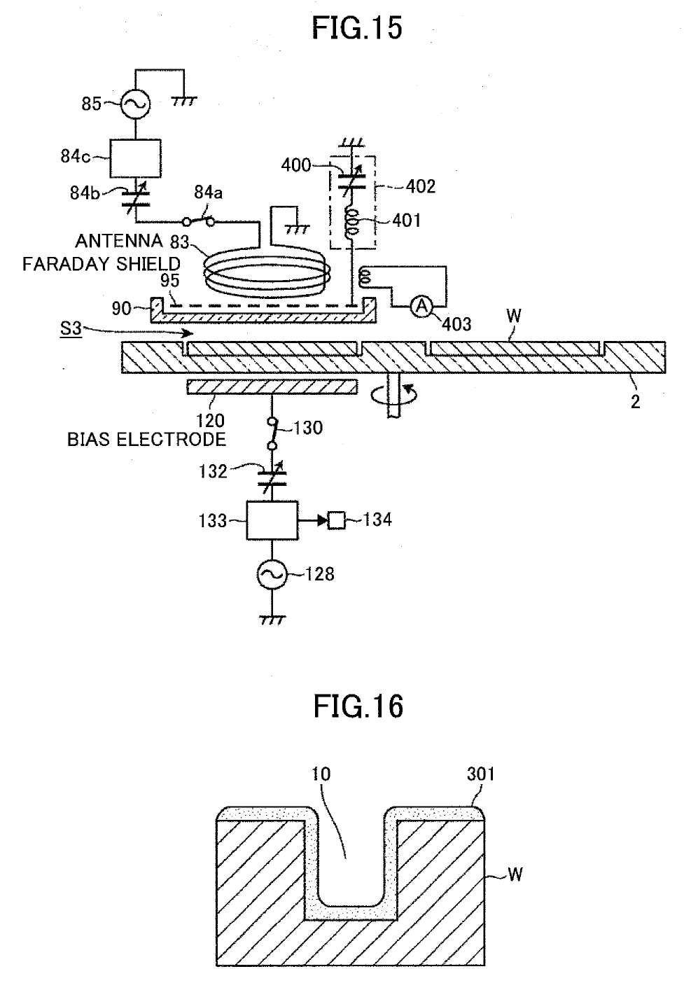

Referring to FIG. 15, a high-frequency power source 85 as an energy supplying portion having a frequency of, for example, 13.56 MHz and an output power of, for example, 5000 W is connected to the antenna 83 through a switch 84a, a matching box 84b, and a filter 84c. The filter 84c is provided to block (cut) a signal in a frequency band of the high-frequency power source 128 (described below). Referring to FIG. 1, the reference symbol 86 designates a connection electrode for electrically connecting the antenna 83 to the high-frequency power source 85 (described below).

The lower surface of the casing 90 forms a protruding portion 92 for regulating a gas. The protruding portion 92 prevents a nitrogen gas or an ozone gas from intruding into the lower area of the casing 90. For this, referring to FIG. 1, the outer edge portion vertically protrudes onto the lower side along the periphery of the protruding portion 92. The above-described plasma generating gas nozzle 34 is accommodated in an area surrounded by the inner peripheral surface of the protruding portion 92, the lower surface of the casing 90, and the upper surface of the turntable 2.

Referring to FIGS. 1, 4, and 6, a faraday shield 95 having an opening on the upper surface side is arranged as an opposing electrode between the casing 90 and the antenna 83. The Faraday shield 95 is formed by a metallic plate that is a conductive plate-like member. The Faraday shield 95 is arranged so that the level plane of the Faraday shield 95 is parallel to the wafers W on the turntable 2.

Slits 97 are formed so as to prevent components of an electric field included in an electric and magnetic field (i.e., an electromagnetic field) generated by the antenna 83 from moving downward toward the wafer W and so as to cause a magnetic field included in the electromagnetic field to reach the wafers W. The slits 97 are formed so as to extend in a direction orthogonal to a direction of winding the antenna 83 and are provided at a position below and along the peripheral direction of the antenna 72. A reference symbol 94 designates an insulating plate made of, for example, quartz. The insulating plate 94 insulates the Faraday shield 95 from the antenna 83.

Referring to FIG. 15, an electric circuit pertinent to the Faraday shield 95 is described. The Faraday shield 95 is grounded through a bias lead-in circuit 402 including, for example, a variable-capacitance capacitor 400 or an inductance 401. In the bias lead-in circuit 402, a detecting portion 403 for detecting an electric current value is provided on a front stage side (the side of the Faraday shield 95). Based on a detection value obtained by the detecting portion 403, for example, a capacitance value of the variable-capacitance capacitor 400 is adjusted by an actuator (not illustrated). Specifically, an impedance between the Faraday shield 95 and the bias electrode 120 is adjusted so that the electric current value exceeds a predetermined setup value in the vicinity of the maximum value. Thus, it is possible to prevent a high frequency from flowing through an unusual path and to restrict an abnormal electric discharge.

Alternatively, the control part 200 (described below) may automatically adjust the impedance between the Faraday shield 95 and the bias electrode 120. When the impedance is automatically adjusted, it may be configured to measure the impedance (mainly, components of reactance) between the Faraday shield 95 and the bias electrode 120 instead of the detection of the electric current value by the detecting portion 403 or together with the detected electric current value. Based on a change of the impedance, it is possible to previously determine how the capacitance value of the variable-capacitance capacitor 400 is adjusted, and specifically whether the capacitance value is increased or decreased in a case where the impedance increases. For example, the control part 200 may automatically adjust the impedance while monitoring a control parameter (an electric current value or an impedance) or may previously match the impedance. Therefore, in a case where the impedance is automatically adjusted using the control part 200, an abnormal electrical discharge is prevented during the plasma process.

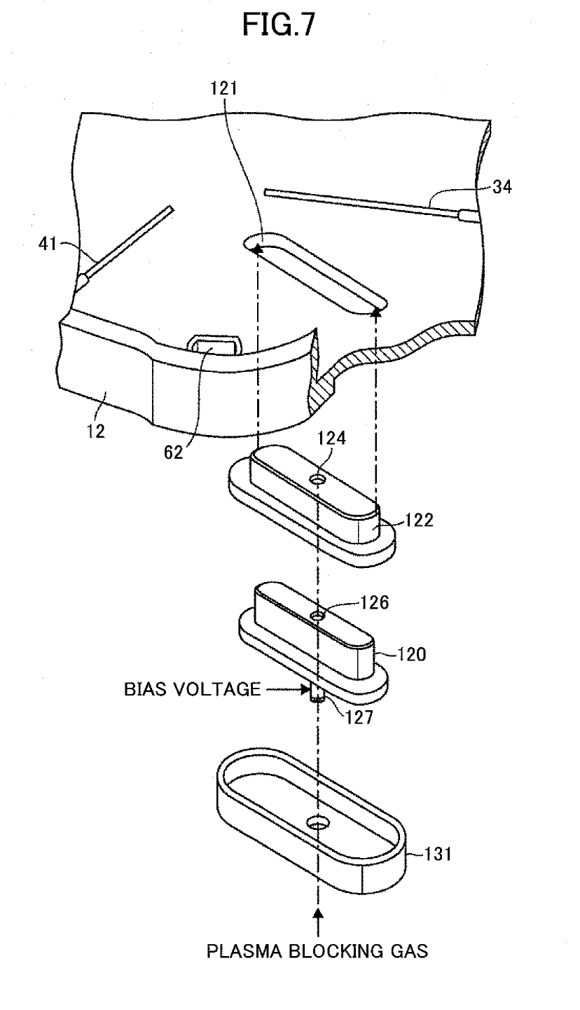

Referring to FIGS. 1 and 7, an opening portion 121 is formed on the side lower than the Faraday shield 95 in the bottom surface portion of the vacuum chamber 1 at a position overlapping the area where the antenna 83 is provided in the plan view of the vacuum chamber 1. Specifically, the position of the turntable 2 is separated onto the downstream side of the rotational direction of the turntable 2 relative to the above described plasma generating gas nozzle 34 in a plan view of the turntable 2. The opening portion 121 has a shape elongated along a radius direction of the turntable 2 from the side of the rotational center to the side of the outer edge of the turntable 2.

Referring to FIGS. 7 and 8, the insulating member in a substantially cylindrical shape is hermetically inserted from the lower side of the turntable 2. The shape of the insulating member 122 has an opening opened on the lower side and has a shape elongated along a radius direction of the turntable 2 in a manner similar to the opening portion 121. The outer peripheral end of the insulating member 122 outward extends like a flange on the side of the lower end along the peripheral direction and hermetically contacts the bottom surface portion of the vacuum chamber 1 using a sealing member such as an O-ring provided on the upper surface side of the outer peripheral end. Hereinafter, an plasma unexcited area S2 exists between the insulating member 122 and the turntable 2. A gas ejection port 124 is formed at a substantially central portion on the upper surface of the insulating member 122. The gas ejection port 124 vertically penetrates the insulating member 122 to eject a plasma blocking gas (described below) toward the plasma unexcited area S2. In this example, the insulating member 122 is made of a dielectric material such as quartz.

Next, the bias electrode 120 is described in detail. This bias electrode 120 is provided to form a bias electric field by performing capacitively coupling between the bias electrode 120 and the Faraday shield 95 and lead ions inside the plasma into the wafers W on the turntable 2. This bias electrode 120 is arranged so as to positionally correspond to the reformulation area S1 and is positioned on the lower side of the turntable 2. Referring to FIG. 3, the bias electrode 120 is arranged so as to bridge between one end of the wafer W on the side of the rotational center and another end of the wafer W on the side of the outer edge when the wafer W is positioned on the upper side of the bias electrode 120. The bias electrode is accommodated inside the insulating member 122 described above. As illustrated in FIG. 8, the bias electrode 120 has a substantially cylindrical shape where the lower end side has an opening and the outer peripheral end on the lower end side outward extends like a flange. The bias electrode 120 is formed in a size smaller than the insulating member 122. According to the example, the bias electrode 120 is made of a conductive member such as nickel (Ni) or copper (Cu).

Referring to FIG. 15, a high-frequency power source 128 having a frequency of 50 kHz to 40 MHz and an output power of 500 W to 5000 W is electrically connected to the bias electrode 120 (specifically, a flow path member 127) described later through a switch 130, a matching box 132, and a filter 133. In this example, the frequency of the high-frequency power source 128 and the frequency of the high-frequency power source 85 for generating plasma (described above) are different. The frequency of the high-frequency power source 128 is 13.56 MHz to 100 MHz. The ground terminal of the high-frequency power source 128 and the ground terminal of the bias lead-in circuit described above are mutually connected by an electrically-conducting path (not illustrated).

The filter 133 is provided to cut a signal in the frequency band of the high-frequency power source 85 for generating plasma and is connected to a current detecting portion 134 for detecting an electric current value flowing through, for example, the filter 133. The current detecting portion 134 may be structured so as to detect the voltage in the filter 133 instead of the electric current value or together with the electric current value.

As illustrated by a broken line in FIG. 3, the bias electrode 120 is arranged so as not to simultaneously correspond to two wafers W, which are adjacent each other, so as not to simultaneously apply a bias electric field to these two wafers W. Said differently, referring to FIG. 9, the width t of the bias electrode 120 in the rotational direction of the turntable 2 is smaller than the distance d between the concave portions 24, 24, which are mutually adjacent on the turntable 2. The width t of the bias electrode 120 is specifically 20 mm to 90 mm (width t=distance d×(50% to 90%). Hereinafter, a reason why the width t of the bias electrode is determined as described above is explained in detail.

When high frequency power is supplied to the bias electrode 120 as described below, the voltage becomes higher at the center portion of the bias electrode 120 than at the peripheral edge portion in the plan view of the bias electrode 120. Therefore, when an end portion of the wafer W reaches the upper side of the bias electrode 120 after moving from the upstream side in the rotational direction of the turntable 2, a relatively strong bias voltage corresponding to the voltage in the center portion of the bias electrode 120 is applied to the end portion of the wafer W.

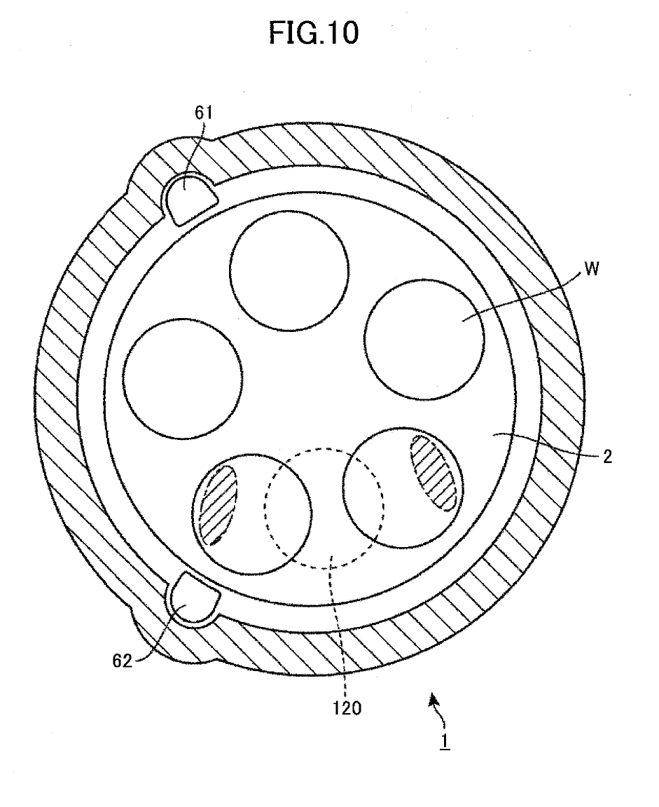

Then, this relatively strong bias voltage is transmitted along a peripheral direction of the wafer W thereby possibly generating plasma in an unintended area. Specifically, as illustrated in FIG. 10, plasma is possibly generated at a position shifted onto the upstream side in the rotational direction of the turntable 2 relative to the reformulation area S1. In a case where the plasma is generated at the unintended position as described above, an unintended reaction (generation of particle) possibly occurs or a damage possibly occurs on the wafer W. Further, when the wafer W is about to leave from the reformulation area S1, an end portion of the wafer W on the upstream side of the rotational direction of the turntable 2 is applied with a relatively strong voltage in a manner similar to the reaching of the wafer W. Therefore, plasma is possibly generated at the end on the opposite side (the downstream side in the rotational direction of the turntable 2) already positioned outside the reformulation area S1. Referring to FIG. 10, a portion where the plasma is generated other than the reformulation area is hatched by diagonal lines surrounded by dot chain lines.

Further, in a case where the bias electrode 120 is arranged so as to bridge two wafers W, which are adjacent each other, in a plan view, the bias electric field is applied to each of the two wafers W. Therefore, if the bias electric field is simultaneously applied to each two wafers W, degrees of the plasma process of five wafers on the turntable 2 are possibly not uniform. Said differently, the heights of the surfaces of the wafers W differ depending on, for example, deformation or wobbling in the rotational shaft 22 or slight errors in the thicknesses of the wafers W or the depths of the concave portions 24. Further, the height of the surface of a specific wafer W among the five wafers W change at each reach of the specific wafer W to the reformulation area S1 during the rotation of the turntable 2 due to the deformation or the like described above.

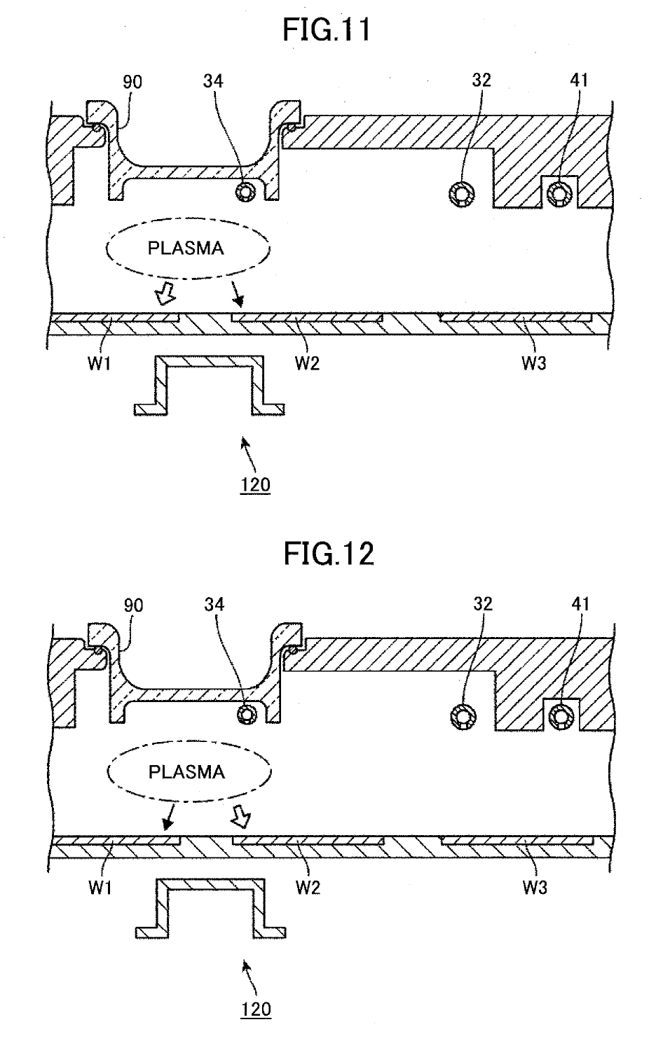

Therefore, as illustrated in FIGS. 11 and 12, a greater bias electric field is possibly applied to the one of the two wafers W than the other of the two wafers W. Further, the relative height of each two wafers W changes for each combination of the wafers W, which are adjacent each other. Therefore, degrees of the plasma process are not uniform among the wafers W. Referring to FIGS. 11 and 12, the wafer on the downstream side in the reformulation area S1 is designated by a reference symbol W1, and the wafer on the upstream side in the reformulation area S1 is designated by a reference symbol W2. Then, referring to FIG. 11, the bias electric field is greater in the wafer W1 than in the wafer W2. Meanwhile, referring to FIG. 12, the bias electric field is greater in the wafer W2 than in the wafer W1.

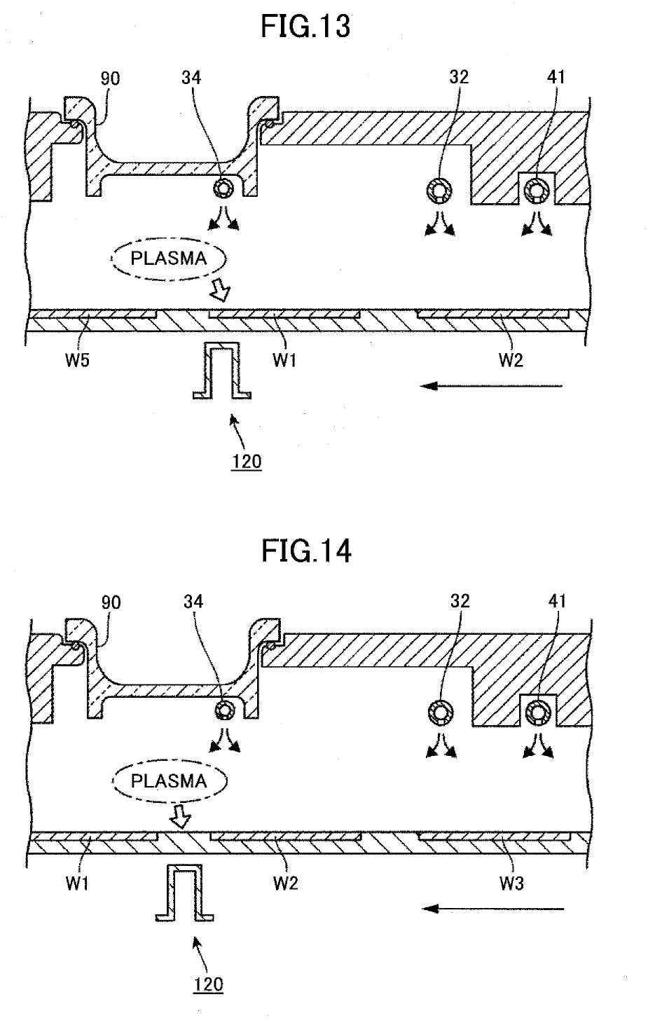

Therefore, as described above, the width t of the bias electrode 120 is set smaller than the distance d of the wafers W (the concave portions 24), which are adjacent each other. Therefore, while the plasma process is performed for one of the five wafers W, the plasma does not irradiate (the bias electric field is not applied to) the other four wafers W as illustrated in FIGS. 13 and 14, or even if the plasma irradiates the other four wafers W, the plasma intensity to the other four wafers W is lower than that to the one of the five wafers W. Said differently, when the one (the wafer W1) of the of the five wafers W is positioned on the upper side of the bias electrode 120, the plasma process is performed for the wafer W1. Next, when the one of the five wafers W (the wafer W1) is about to leave from the reformulation area as illustrated in FIG. 14, the wafer W2 positioned on the upstream side of the rotational direction of the turntable 2 relative to the wafer W1 does not overlap the bias electrode 120 and is separated from the bias electrode 120 on the upstream side. When the wafer W2 reaches the area on the upper side of the bias electrode 120, the wafer W1 is already separated from the area onto the downstream side of the rotational direction of the turntable 2. Therefore, the plasma process (the application of the bias electric field) is individually performed for each wafer W.

Subsequently, the structure of the bias electrode 120 is described. As illustrated in FIG. 8, the outer peripheral end of the bias electrode 120 on the lower end side is arranged so as to position closer to the inner side from the outer end side of the insulating member 122 in order to avoid a contact of the bias electrode 120 with the bottom surface portion of the vacuum chamber 1. The bias electrode 120 is hermetically arranged to the insulating member 122 by a sealing member 125 such as an O-ring, which is provided on the upper surface side of the outer peripheral end of the bias electrode 120. Therefore, the bias electrode 120 is arranged so as not to contact (non-contact) the turntable 2 and to electrically insulated from the vacuum chamber 1.

A through opening 126 is formed at a substantially central portion of the bias electrode 120 so as to vertically penetrate through the upper end surface of the bias electrode 120 and correspond to a position where the gas ejection port 124 of the insulating member 122. As illustrated in FIG. 1, the flow path member 127 made of a conductive member is hermetically connected onto the lower side of the through opening 126. The flow path member 127 is provided to supply a plasma blocking gas (e.g., a nitrogen (N₂) gas or a helium (He) gas) into the plasma unexcited area S2.

As illustrated in FIG. 1, a sealing member 131 is provided on the lower side of the bias electrode 120. The sealing member 131 is made of an insulating material such as quartz and has a substantially disk-like shape.

The outer peripheral end of the sealing member 131 stands toward the insulating member 122 on the upper side along the peripheral direction between the bottom surface portion of the vacuum chamber 1 and the outer peripheral end of the bias electrode 120. Therefore, when the insulating member 122, the bias electrode 120, and the sealing member 131 are inserted in this order into the opening portion 121 of the vacuum chamber 131, and simultaneously the sealing member 131 is fixed to the bottom surface of the vacuum chamber 1 by, for example, a bolt (not illustrated), the insulating member 122 hermetically contact the vacuum chamber 1. Further, the bias electrode 120 hermetically contact the insulating member 122. Further, the sealing member 131 electrically insulates the bias electrode 120 from the vacuum chamber 1.

As illustrated in the enlarged view on the lower side of FIG. 8, the upper surface of the insulating member 122 is located inside the groove portion 2a on the lower surface side of the turntable 2 and the wafer W on the turntable 2 and the bias electrode 120 are arrange in parallel along the lower surface side of the turntable 2. The distance between the lower surface of the turntable 2 and the upper surface of the insulating member 122 is, for example, 0.5 mm to 3 mm. Referring to FIG. 7, the sealing members 123 and 125 are not illustrated.

A ring-like side ring 100 is arranged on the outer peripheral side of the turntable 2. A gas flow route 101 in a groove-like shape is formed on the upper surface of the side ring 100 on the outer edge side of the casing 90 to cause a gas to flow without interruption by the casing 90. Evacuation ports 61 and 62 respectively corresponding to the first and second process areas P1 and P2 are formed on the upper surface of the side ring 100. As illustrated in FIG. 1, evacuation pipes 63 extending from the first and second evacuation ports 61 and 62 are connected to an evacuation mechanism such as a vacuum pump 64 through a pressure adjuster 65 such as a butterfly valve.

Referring to FIGS. 2 and 4, a transfer opening 15 is formed in a side wall of the vacuum chamber 1. The transfer opening 15 is provided to send or receive the wafer W between a transfer arm (not illustrated) located outside the transfer opening 15 and the turntable 2. The transfer opening 15 can be opened or hermetically closed using a gate valve G. Further, a lift pin (not illustrated) for lifting the wafer W from the back surface side of the wafer through a through hole (not illustrated) of the turntable 2 is provided on the lower side of the turntable 2 at a position corresponding to the transfer opening 15.

Therefore, the above-described structure including the bias electrode 120 and the Faraday shield 95 forms a pair of opposing electrodes as illustrated in FIG. 15, where when the wafer W is positioned on the lower side of the reformulation area S1, the bias electrode 120 and the Faraday shield 95 are positioned so as to overlap the wafer W in the plan view of the vacuum chamber 1. Referring to FIG. 15, when high frequency power is supplied from the high-frequency power source 128 to the bias electrode 120, capacitively coupling is formed between the opposing electrodes to thereby generate a bias space S3. Therefore, ions inside plasma, which are generated inside the vacuum chamber 1 by the plasma process portion 80, vertically oscillate (move) inside the bias space S3 as described below. Therefore, when the wafer W is positioned inside the bias space S3 by the rotation of the turntable 2, the ions vertically moving collide against the wafer W. Therefore, the ions are drawn into the wafers W. Referring to FIG. 1, the electric circuit described above is omitted from illustration.

Further, the film forming deposition apparatus includes a control part 200 having a computer for controlling entire operations of the film deposition apparatus. A program for performing a process of deposition a film and a plasma reformulation process is stored in a memory of the control part 200. When the plasma reformulation process is performed, the control part 200 has a feedback function for adjusting the plasma density generated inside the vacuum chamber 1. Specifically, the control part 200 is structured so as to adjust the reactance of the filter 133 and the capacitance value of the matching box 84b based on the electric current value of an electric current flowing through the filter 133 connected bias electrode 120. The program is made to perform steps of the following operations of the film deposition apparatus. The program is installed in the control part 200 from a memory part 201 being a recording medium such as a hard disk, a compact disk, a magneto-optical disk, a memory card, and a flexible disk.

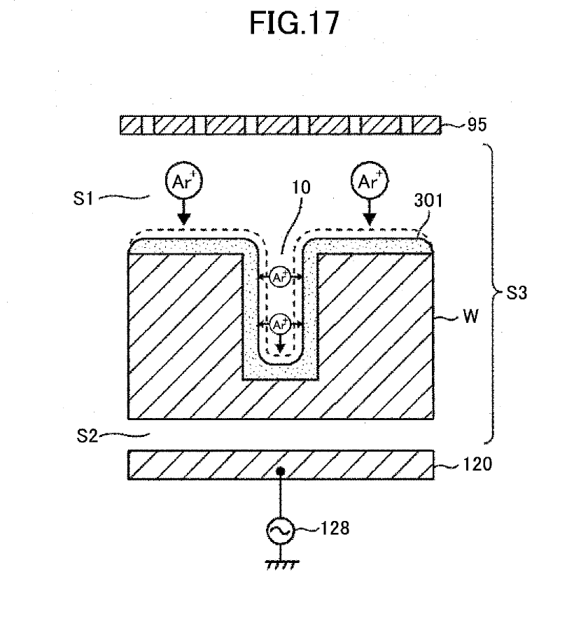

Next, functions of the above embodiment are described. At first, the gate valve G is released. While the turntable 2 is intermittently rotated, for example, five wafers W are mounted onto the turntable 2 by the transfer arm (not illustrated) through the transfer opening 15. A depressed portion 10 (see FIG. 16) such as a groove or a hole is formed on the surfaces of the wafers W. An aspect ratio (i.e., the depth of the depressed portion 10/the width of the depressed portion 10) is, for example, several tens to more than a hundred). Subsequently, the gate valve G is closed. The inside of the vacuum chamber 1 is completely evacuated by the vacuum pump 64, and simultaneously the turntable 2 is rotated at 2 rpm to 240 rpm in the clockwise direction. Then, the wafer W is heated to, for example, about 300° C. by the heater unit 7.

Subsequently, the first process gas and the second process gas are discharged from the process gas nozzles 31 and 32, respectively, and simultaneously the plasma generating gas is discharged from the plasma generating gas nozzle 34. Further, a plasma blocking gas is discharged to the plasma unexcited area S2 so that the gas pressure in the area S2 is a positive pressure (a high pressure) relative to the reformulation area S1 so as to prevent the plasma from generating in the area S2. This plasma blocking gas flows on the lower side of the turntable 2 and is exhausted from the evacuation port 62.

A separation gas is supplied at a predetermined flow rate from the separation gas nozzles 41 and 42. Further, a N₂ gas is supplied at a predetermined flow rate from the separation gas supplying pipe 51 and the purge gas supplying pipes 72, 72. The inside of the vacuum chamber 1 is adjusted to have a predetermined process pressure by the pressure adjuster 65. Further, high frequency power is supplied to the antenna 83 and the bias electrode 120.

Within the first process area P1, components of the first process gas adsorbs onto the surface of the wafer W to thereby produce an adsorption layer. Subsequently, a reaction layer 301 is formed in the second process area P2. The reaction layer 301 is formed such that the adsorption layer on the wafer W is oxidized to form one or a plurality of molecular layers of silicon oxide (SiO₂) film as thin film components as illustrated in FIG. 16. Impurities such as moisture (a hydroxyl group, an OH group) or organic matter may remain in the reaction layer 301 by a residual base contained in, for example, the first process gas.

In the plasma process portion 80, an electric field and a magnetic field are generated by high frequency power supplied from the high-frequency power source 85. The electric field included in the generated electric field and magnetic field are reflected or absorbed (attenuated) by the Faraday shield 95 to thereby prevent the electric field from reaching inside the vacuum chamber 1. Meanwhile, the magnetic field reaches the reformulation area inside the vacuum chamber 1 after passing through the slits 97 formed in the Faraday shield 95 and the bottom surface of the casing 90.

Therefore, the plasma generating gas discharged from the plasma generating gas nozzle 34 is activated by the magnetic field thereby generating plasma such as ions (argon ions: Ar+) or radicals. As described, since the antenna 83 is arranged in the radius direction of the turntable 2 so as to surround the belt-like area, the plasma may be shaped substantially like a line extending in the radius direction of the turntable 2.

Here, the plasma is prone to distribute along a horizontal plane along the winding direction of the antenna 83. However, the electric field is formed by the capacitively coupling between the Faraday shield 95 and the bias electrode 120. Therefore, the electric field is applied to the ions inside the plasma in the vertical direction, and therefore the ions are lead to the side of the wafer W as described above. Therefore, as illustrated in FIG. 17, the ions inside the plasma reaches and contacts not only the surfaces of the wafers W (the horizontal surface between the adjacent depressed portions) but also the inner wall surfaces of the depressed portions 10 and the bottom surfaces of the depressed portions 10. Thus, when the argon ions collide against the reaction layer 301, the impurities such as moisture or organic matter are released, or elements inside the reaction layer 301 is rearranged so that the reaction layer 301 is densified (highly densified) to thereby reformulate the reaction layer 301. Therefore, the reformulation is evenly performed along the surfaces of the wafers and along the depths of the depressed portions 10. Further, as described above, because the width t of the bias electrode 120 is determined to be smaller than the distance t of the adjacent wafers and the bias electrode field is individually formed for each wafer W, the reformulation process are uniformly performed for the five wafers W.

Thereafter, while the turntable 2 continues to rotate, the adsorption in the adsorption layer, the generation of the reaction layer 301, and the reformulation of the reaction layer 301 are performed in this order many times. Resultantly, the thin film is formed by the lamination of the reaction layer 301. This thin film has a dense and uniform film property along the depths of the depressed portions 10 and along the surfaces of the wafers W. Referring to FIG. 17, the Faraday shield 95, the bias electrode 120 and the wafer W are schematically illustrated.

Because the nitrogen gas is supplied to the area between the first process area P1 and the second process area P2 while the above series of the processes are performed, the first process gas, the second process gas, and the plasma generating gas are exhausted so as not to mutually mix. Further, since the purge gas is supplied to the lower side of the turntable 2, the exhaust gas diffusing below the turntable 2 is pushed back toward the evacuation ports 61 and 62 by the purge gas.

Within the above embodiment, when the plasma process is performed for the plurality of wafers W which orbitally revolves around on the turntable 2, the bias electrode 120 is placed at the position facing the reformulation area S1 on the lower side of the turntable 2. The width t of the bias electrode 120 in the rotational direction of the turntable 2 is made smaller than the distance d of the adjacent wafers W. Therefore, it is possible to individually form the bias electric field for each wafer W and lead ions included in plasma onto the wafers W while restricting the bias electric field from being simultaneously applied to the adjacent wafers W. Therefore, even if a large depressed portion 10 having a large aspect ratio is formed on the surface of the wafer W, thin films having uniform film properties can be deposited along the depth direction of the depressed portion 10, along the surfaces of the wafers W, and along the plurality of wafers W.

Further, because the bias space S3 is formed immediately below the plasma process portion 80 and the reformulation area S1 overlaps the bias space S3, it is possible to restrict unnecessary plasma from generating in an area other than the reformulation area S1. As described, although it is intended to generate the plasma in the position lower than the antenna 83, the plasma may unintentionally generate or diffuse at, for example, a place where the pressure inside the vacuum chamber 1 is locally low or a place where a metallic surface such as the inner wall surface is exposed. For example, when this unintentionally generated or diffused plasma interferes with a Si gas, the Si gas is decomposed before the Si gas adsorbs onto the wafer W. In this case, the film property is degraded. However, as described above, the bias space S3 is formed on the lower side of the antenna 83 in order to lead the plasma (the ions) onto the side of the wafer W. Therefore, it is possible to prevent plasma from unintentionally generating while performing the plasma reformulation process.

Further, because the capacitively coupling between the Faraday shield 95 and the bias electrode 120 is formed to lead the ions into the side of the wafer W, when the ions collide against the wafer W, the energy of the ions are converted into heat by the collision of the ions to thereby increase the temperature of the wafer W. This temperature change (the temperature increase) of the wafer W is proportional to the electric energy supplied to the high-frequency power source 128. Therefore, when the reaction product on the wafer W undergoes the reformulation, not only ions are supplied to the wafer W but also the temperature of the wafer W is increased. Therefore, the film property becomes better as much as the temperature increase of the wafer W. The high frequency for the bias is not limited to the single frequency and may be two frequencies (using two high-frequency power sources having different frequencies), or three frequencies or greater frequencies. Said differently, it is possible to adjust a degree of the plasma process between the central portion of the wafer W and the outer edge portion of the wafer W by connecting high-frequency power sources having different frequencies to the bias electrode 120. Therefore, it is possible to form a thin film having a uniform film property along the surface of the wafer W.

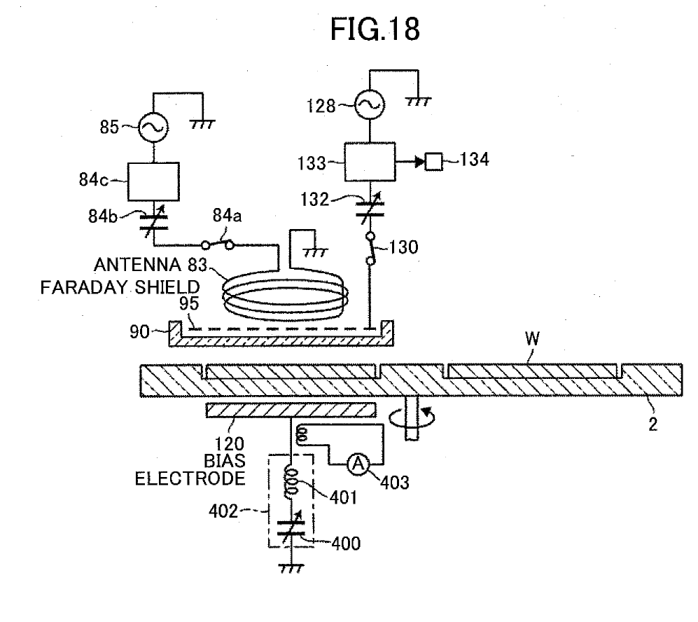

FIG. 18 illustrates an example that the high frequency power source 128 is connected with the Faraday shield 95 instead of the bias electrode 120 as the structure of the capacitively coupling between the Faraday shield 95 and the bias electrode 120. The bias electrode 120 is grounded through the bias lead-in circuit. As described, in a case where the high-frequency power source 128 is connected with the Faraday shield 95, the high-frequency power source 85 for generating plasma may be used. Said differently, without using the high-frequency power source 128, the antenna 83 and the Faraday shield 95 are connected in parallel and further connected with the high-frequency power source 85. Referring to FIG. 18, the above described members are attached with the above described reference symbols and explanation of the above described members is omitted. Further, the structure of the vacuum chamber 1 is simplified in FIG. 18.

Further, although the bias electrode 120 is arranged on the lower side of the antenna 83 within the embodiment, the bias electrode 120 may be positionally shifted on, for example, the upstream side of the rotational direction relative to the antenna 83 in a case where the distribution shape of plasma is adjusted in the rotational direction of the turntable 2. Therefore, the position of the bias electrode 120 at “the position facing the reformulation area S1 on the lower side of the turntable 2” described above is not limited to a position immediately below the reformulation area S1 and includes a position separated from the reformulation area S1 by 0 mm to 100 mm on the downstream side or the upstream side in the rotational direction of the turntable 2.

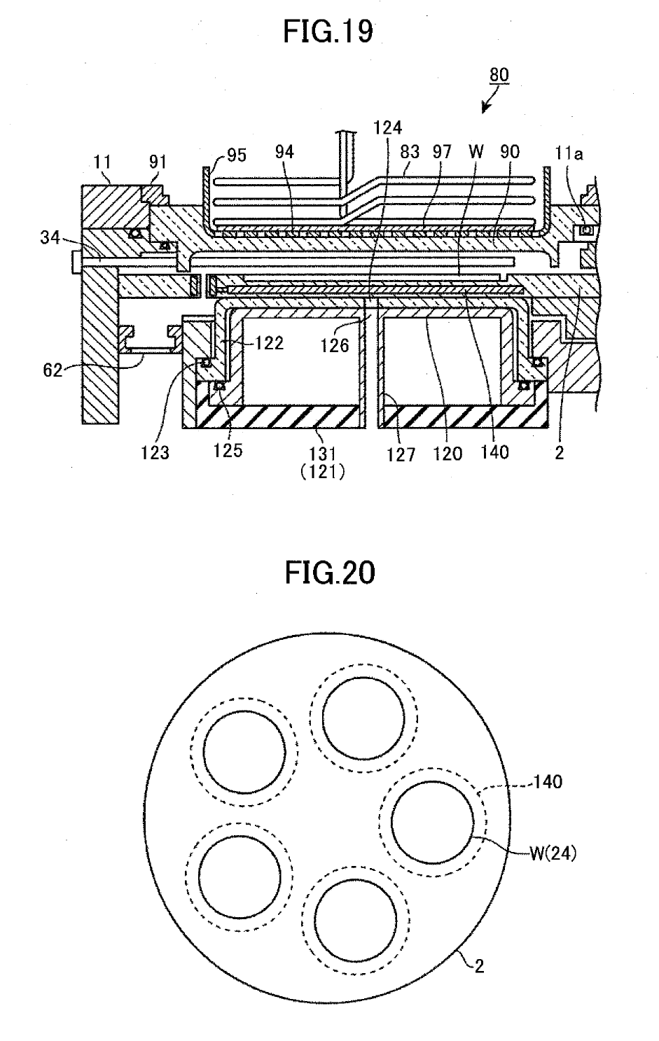

Further, referring to FIGS. 19 and 20, a disk-like auxiliary electrode 140 containing at least one of a conductor such as a metal like copper (Cu) or aluminum (Ai) and a semiconductor such as Si may be embedded inside the turntable 2. As illustrated in FIG. 20, the auxiliary electrode 140 is individually provided for each wafer W and has a size equal to or greater than an area of projecting the wafer W in the plan view of the turntable 2. As described, when the auxiliary electrode 140 is embedded inside the turntable 2, the capacitively coupling between the Faraday shield 95 and the bias electrode 120 is interposed by the auxiliary electrode 140. Therefore, the wafer W can be made electrically closer on the side of the bias electrode 120 by the thickness of the auxiliary electrode 140. As a result, it is possible to further enhance a function of leading ions into the wafer W.

When electric power is supplied to the auxiliary electrode 140, the turntable 2 and the rotational shaft 22 may be made of conductive material and the electric power may be supplied to the rotational shaft 22 using, for example, a slip ring mechanism (not illustrated).

Further, although the terminal of the antenna 83 at one end is connected with the high-frequency power source 85 and the other terminal of the antenna 83 at the other end is grounded within the above embodiment, the terminal and the other terminal may be connected with the high-frequency power source 85.
Further, the terminal of the antenna 83 at the one end is connected with the high-frequency power source 85 and the terminal of the antenna 83 at the other end may be floated (supported while being spaced from surrounding conductive portions).

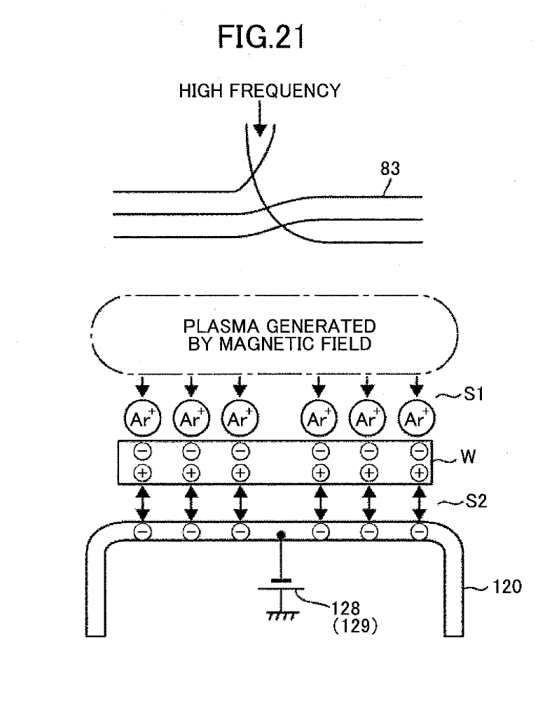

Furthermore, although the capacitively coupling between the Faraday shield 95 and the bias electrode 120 is used in leading the ions included the plasma onto the side of the wafer W within the above embodiments, electrostatic coupling between the wafer W and the bias electrode 120 may be used. Said differently, the state at an instant when electric power is supplied from the high-frequency power source 128 to the bias electrode 120 without providing the Faraday shield 95 is equal to a state where a negative direct voltage is applied to the bias electrode 120 as illustrated in FIG. 21. Said differently, under this state, electrons are supplied from the high-frequency power source 128 to the bias electrode 120 and the bias electrode 120 is charged to be negative. The bias electrode 120 does not contact the wafer W and electrically insulated. Further, in the unexcited area S2, the plasma is prevented from generating as described above. Therefore, when the wafer W reaches on the upper side of the bias electrode 120, electric charges are not balanced in the thickness direction of the bias electrode 120 by electrostatic induction caused in the wafer W by the negative direct current in the bias electrode 120. Said differently, electrons inside the wafer W move onto the surface side of the wafer W by the repulsive force caused by the negative direct current. The electron mobility (the amount of charge of the wafer W on its surface side) becomes uniform along the surface of the wafer W because the upper surface of the bias electrode 120 is parallel to the wafer W.

Meanwhile, the state at another instant when high frequency power is supplied from the high-frequency power source 128 to the bias electrode 120 is equal to a state where a positive direct voltage is applied to the bias electrode 120. Therefore, positive electric charges (protons) are ready to move from the high-frequency power source 128 to the bias electrode 120. However, because a high frequency is used in the high-frequency power source 128 as described above, a positive direct voltage and a negative direct voltage are changed over at a high speed. Therefore, a time period while the positive direct voltage is applied to the bias electrode 120 (a time period while a polar character applied from the high-frequency power source 128 is maintained) is extremely short. Because the mass of proton is greater than that of electron by about triple digits, protons are less movable than electrons. Therefore, before protons reach the bias electrode 120 from the high-frequency power source 128, the polar character of the high-frequency power source 128 is changed over. At this time, because the electrons can immediately reach the bias electrode 120, the bias electrode 120 remains negatively charged. Thus, positive ions, specifically argon ions, in the reformulation area S1 are attracted on the side of the wafer W due to the negative electric charges on the surface of the wafer W.

In a case where the electrostatic coupling between the bias electrode 120 and the wafer W is used as described above, the Faraday shield 95 may be arranged between the antenna 83 and the reformulation area S1. In this case, a terminal of the antenna 83 on the side of the ground and a terminal of the bias electrode 120 (the high-frequency power source 128) on the side of the ground are separately grounded using different wirings to prevent capacitively coupling. The Faraday shield 95 may be retained so as to electrically float relative to the other conductive members included in the vacuum chamber instead of grounding the Faraday shield 95. Within the above embodiments, as illustrated in FIG. 21, a negative direct power source 129 may be used instead of the high-frequency power source 128.

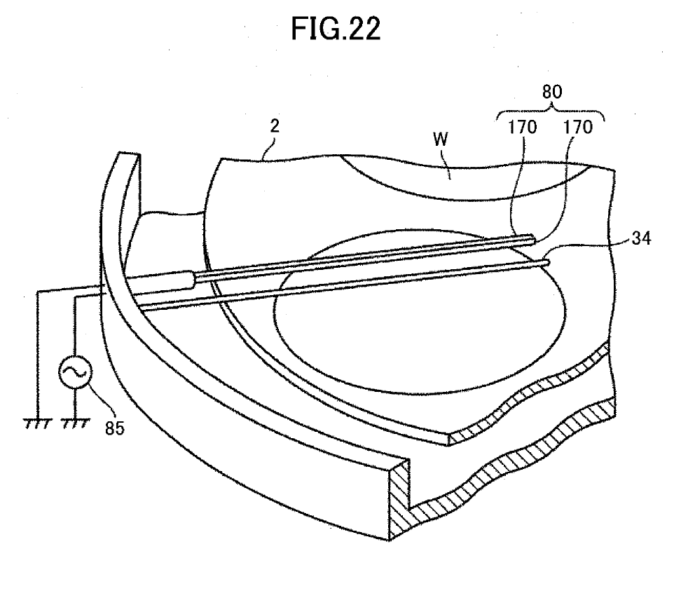

Further, in the above embodiments, the antenna 83 as the plasma process portion 80 is wound to generate inductively coupled plasma (ICP). However, capacitively coupled plasma (CCP) may be generated. In this case, as illustrated in FIG. 22, a pair of opposing electrodes 170, 170 is arranged on the downstream side of the rotational direction of the turntable 2 relative to the plasma generating gas nozzle 34.

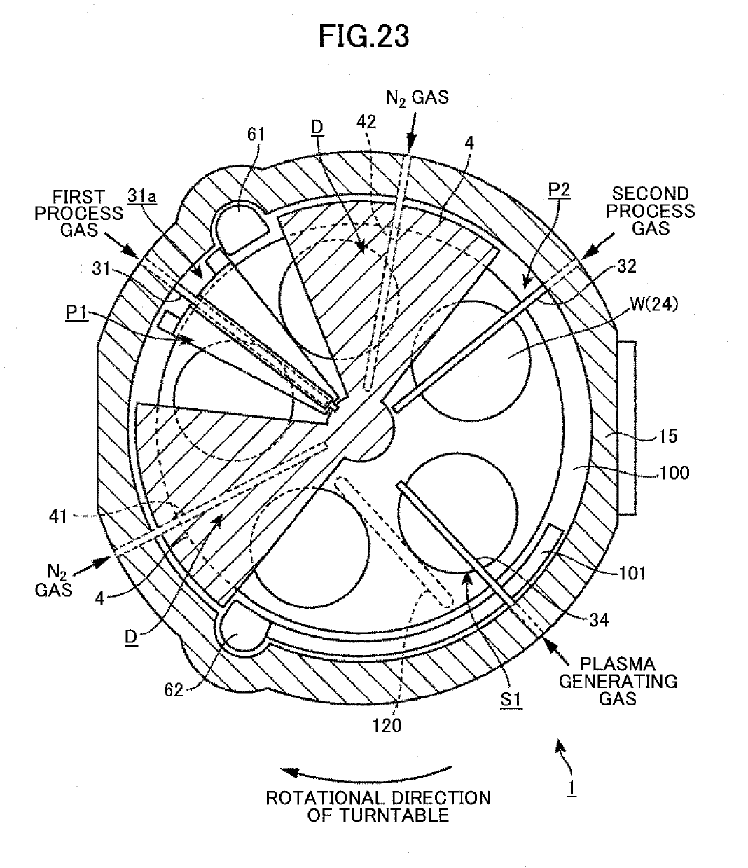

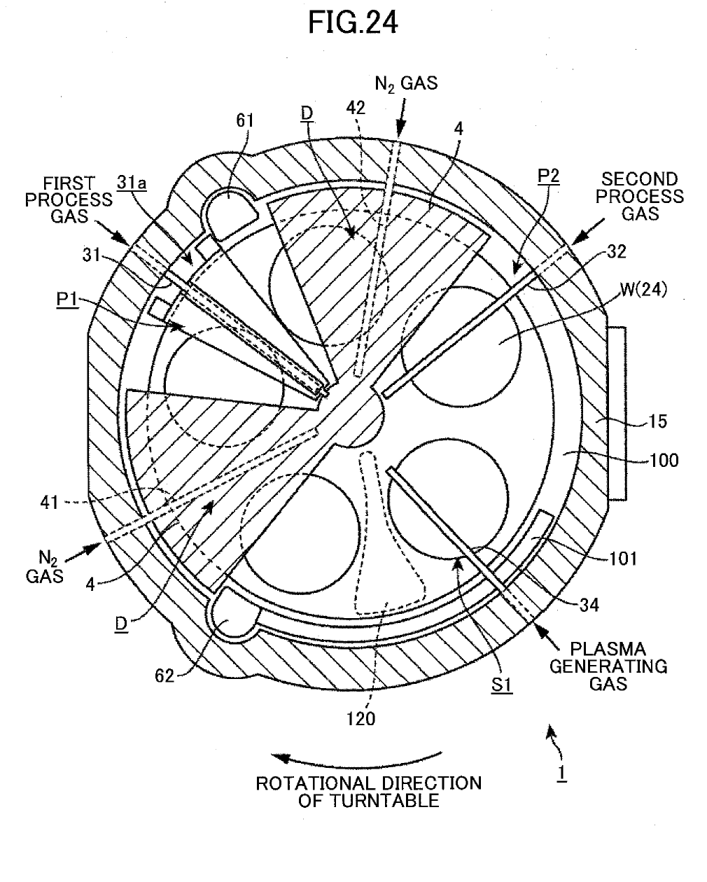

Further, the width t of the bias electrode 120 can be made smaller than the distance d between the adjacent wafers W in the plan view of the vacuum chamber 1 by employing the following structure. FIG. 23 illustrates an exemplary structure where the bias electrode 120 is arranged in parallel with the plasma generating gas nozzle 34 on the downstream side of the rotational direction of the turntable 2 relative to the plasma generating gas nozzle 34. Therefore, the bias electrode 120 is arranged so as to cross an imaginary line extending in a radius direction of the turntable 2 (so as not to be parallel with the imaginary line).

FIG. 24 illustrates an exemplary arrangement of the bias electrode 120 where the bias electrode 120 is substantially widened in a plan view of the vacuum chamber 1 from the center side of the turntable 2 to the outer edge side. The distance d between the adjacent wafers W is relatively great on the rotational center side and the outer edge side of the turntable 2 and relatively small at an area between the rotational center side and the outer edge side of the turntable 2. Said differently, the distance d becomes smallest along a circle connecting the centers of the five wafers W in their plan view and becomes greater along farther concentric circles from the circle connecting the centers of the five wafers W. Therefore, referring to FIG. 24, width t of the bias electrode 120 is partly made smaller than the distance d and is widened toward the outer edge side along the length direction of the bias electrode 120. Therefore, degrees of the plasma process, in the radius direction of the turntable 2 can be matched by preventing a smaller degree of the plasma process on the outer edge side of the turntable 2 than the degree of the plasma process on the center side of the turntable 2, which smaller degree is caused by the rotation of the turntable 2.

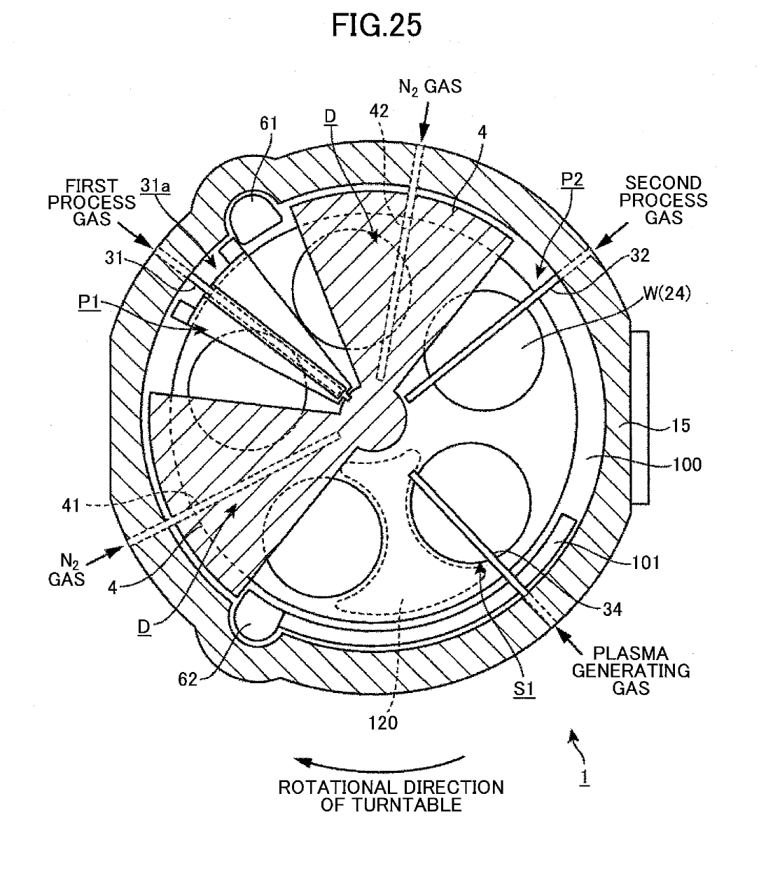

Further, FIG. 25 illustrates an exemplary arrangement of the bias electrode 120 where edge portions of the bias electrode 120 on the upstream and downstream sides are shaped like a substantially circular arc along the outer edges of the wafers. Therefore, when the wafer W on the turntable 2 enters into and leaves from the area on the upper side of the bias electrode 120, the outer edge portion contacts plasma along the radius direction of the turntable 2. Therefore, it is possible to prevent a bias electric field from being locally applied to the edge portion of the wafer W. Referring to FIGS. 24 and 25, the bias electrode 120 is formed so as not simultaneously overlap the two adjacent wafers W in the plan view of the vacuum chamber 1.

Further, although the number of mounting the wafers W on the turntable 2 is five in the above embodiments, this number of mounting the wafers W may be plural, for example, two or greater. As the number of mounting the wafers W on the turntable 2 having a predetermined diameter increases, the distance d between the adjacent wafers W becomes smaller to thereby facilitate the bias electric field to be simultaneously formed. On the other hand, as the number of mounting the wafers W on the turntable 2 increases, the wafers W can be simultaneously processed as many to thereby improve the throughput. Therefore, the number of mounting the wafers W on the turntable 2 is preferably four or greater.

Further, although the length of the bias electrode 120 in the radius direction from the center side to the outer edge side is determined to be longer than the diameter (300 mm) of the wafer W and overlaps the diameter of the wafer W in the above embodiments, the bias electrode 120 may overlap only a part of the diameter. Said differently, in a case where a depressed portion having the above described aspect ratio is formed only on, for example, the central portion in the radius direction of the turntable 2, the bias electrode 120 may be arranged so as to face only the central portion in the radius direction of the turntable 2.

Here, in a case where the bias electrode 120 os arranged on the lower side of the turntable 2 without contacting the turntable 2, a preferable height of the bias electrode 120 is described. When the bias electrode 120 excessively separated from the turntable 2 in arranging the bias electrode 120, plasma (abnormal electrical discharge) may be generated in the unexcited area S2. Therefore, it is preferable to set the bias electrode 120 as closer as possible the turntable 2. However, because the amount of thermal expansion of the turntable 2 changes depending on the heating temperature inside the vacuum chamber 1, the optimal height of the bias electrode 120 varies for each processing recipe. Further, a probability of causing the abnormal electrical discharge is changed depending on the degree of vacuum in the vacuum chamber 1, for example. Further, the optimal height of the bias electrode 120 may vary depending on the rotational speed of the turntable 2 (probability of wobble of the turntable 2) or a processing accuracy on the lower surface of the turntable 2.

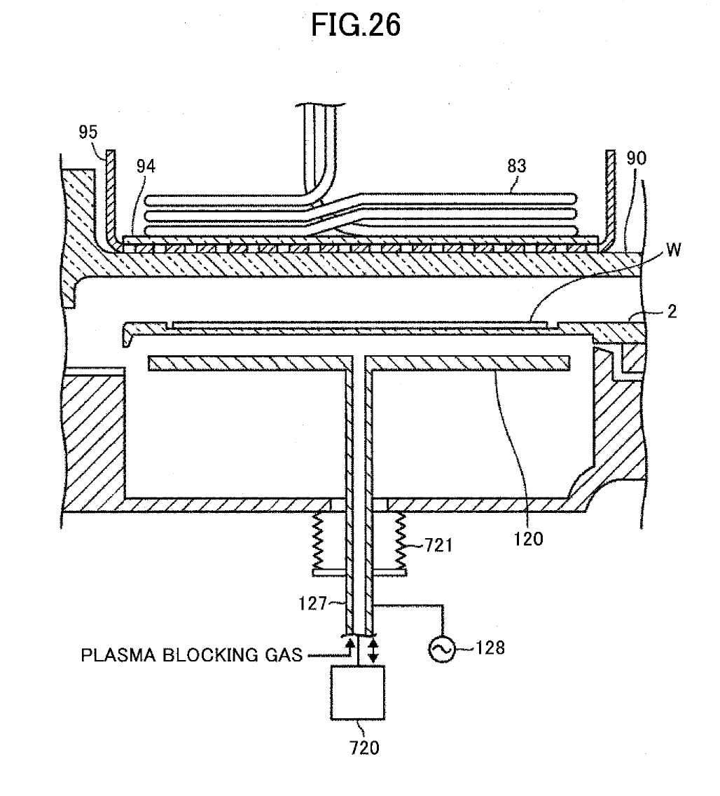

Accordingly, it is preferable to form the bias electrode 120 so as to be freely lifted up and down. FIG. 26 illustrates an example of the bias electrode 120 which can be freely lifted up and down. The flow path member 127 is connected with the lifting mechanism 720 on the lower side of the vacuum chamber 1. A reference symbol is a bellows for hermetically sealing a gap between the flow path member 127 and the bottom surface of the vacuum chamber 1. Meanwhile, the above described insulating member 122 may be provided on the upper side of the bias electrode 120 so that the insulating member 122 can be lifted up and down along with the bias electrode 120, or a coating film made of an insulating material such as quarts may be formed on the surface of the bias electrode 120.

Table 1 shows a result (a voltage) of generating state of plasma in the area between the turntable 2 and the bias electrode 120 obtained by variously changing a distance (a gap) between the lower surface of the turntable 2 and the upper surface of the bias electrode 120 and a high frequency power value supplied to the bias electrode 120. Referring to Table 1, plasma is generated in the unexcited area S2 depending on conditions in a part shaded by light gray, plasma is generated in the unexcited area S2 in a part shaded by dark gray, and plasma is not generated in the unexcited area S2 in a part without shade.

TABLE 1

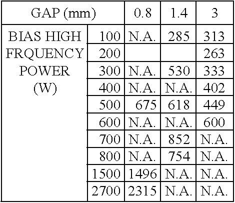

In the test corresponding to Table 1, the high frequency power supplied to the antenna 83 is set to be 1500 W, and the high-frequency power source 83 having a frequency of 40 MHz is connected to the bias electrode 120. Further, a gas supplied onto the lower side of the turntable 2 is a mixed gas of an Ar gas and an O₂ gas (Ar: 700 sccm and O₂: 70 sccm).

Resultantly, it is known that as the distance between the turntable 2 and the bias electrode 120 is smaller, plasma is more hardly generated. Further, it is known that as the high frequency power value for bias becomes smaller, the abnormal electrical discharge is further restricted. Further, when the frequency of the high-frequency power source 128 is set to be 3.2 MHz, a result similar to FIG. 1 is obtained as shown in Table 2.

TABLE 2

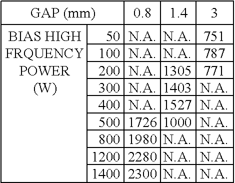

Further, when the bias electrode 120 is formed so be freely lifted up or down, an inert gas may be introduced in the area (the unexcited area S2) between the turntable 2 and the bias electrode 120 to make the pressure inside the unexcited area S2 higher than the inner atmosphere of the vacuum chamber 1. Further, an evacuation route extending from a vacuum pump (not illustrated) is opened to the unexcited area S2 to make the pressure inside the unexcited area S2 be lower than the pressure of the inner area of the vacuum chamber 1.

The first process gas used to deposit the above described silicon oxide film may be a chemical compound listed in Table 3. In the following Tables, “area for raw material A” corresponds to the first process area P1 and “area for raw material B” corresponds to the second process area P2. Further, the following gases are only examples and the above described gases are also listed.

TABLE 3
AREA FOR RAW MATERIAL A
MATERIAL FOR FORMING INSULATING LAYER

DCS (DICHLOROSILANE), TETRAETHOXYSILANE (TEOS),
TETRAMETHYLSILANE (TMS), HCD (HEXACHLORODISILANE),
MONOSILANE [SiH₄], DISILANE [Si₂H₆],
HMDS (HEXAMETHYLDISILAZANE), TCS (TRICHLOROSILANE),
DSA (DISILYLAMINE), TSA (TRISILYLAMINE), BTBAS
(BIS(TERTIARY-BUTYLAMINO)SILANE), 3DMAS
(TRIS(DIMETHYLAMINO)SILANE), 4DMAS
(TETRAKIS(DIMETHYLAMINO)SILANE), TEMASiH
(TRIS(ETHYLMETHYLAMINO)SILANE), TEMASi
(TETRAKIS(ETHYLMETHYLAMINO)SILANE), Si (MMP)₄
(TETRAKIS(METHOXYMETHYLPROPOXY)SILANE)

The second process gas for oxidizing the first process gas listed in Table 3 may be chemical compounds listed in Table 4.

TABLE 4
AREA FOR RAW MATERIAL B
OXIDIZING SEED

O₂ (OXYGEN), O₃ (OZONE)
H₂O (WATER)
PLASMA + O₂
PLASMA + O₃

Referring to Table 4, “PLASMA+O₂” and “PLASMA+O₃” mean that the above described plasma process portion 80 is provided on the upper side of the second process gas nozzle 32 and the oxygen gas or the ozone gas is changed to plasma and used, for example.

Further, the chemical compound listed in Table 3 may be used as the first process gas and a gas made of a chemical compound listed in Table 5 may be used as the second process gas to deposit a silicon nitride film (SiN film).

TABLE 5
AREA FOR RAW MATERIAL B
NITRIDIZING SEED

NH₃ (AMMONIA)
N₂ (NITROGEN)
PLASMA + NH₃
PLASMA + N₂

Referring to Table 5, the indication of “PLASMA” means that gases following the indication of “PLASMA” are changed to plasma in a manner similar to Table 4.

Further, gases made of chemical compounds listed in Table 6 are used as the first and second gases, respectively, to deposit a carbonized silicon (SiC) film.

TABLE 6

| SIDE OF AREA FOR RAW | |
|---|---|
| MATERIAL A | AREA FOR RAW MATERIAL B |
| MATERIAL FOR FORMING SiC | CARBONIZING SEED |
| (FIRST PROCESS GAS) | (SECOND PROCESS GAS) |
| SiH₄, Si₂H₆, | PROPANE (C₃H₈), |
| TETRACHLOROSHILANE (SiCl₄), | ETHYLENE (C₂H₄), |
| TRICHLOROSILANE (SiHCl₃), | ACETYLENE(C₂H₂), |
| DICHLOROSILANE (SiH₂Cl₂) | C₂H₆ (ETHANE) |

Furthermore, a silicon film (Si film) may be deposited using the first process gas listed in Table 1. In this case, the second process gas nozzle 32 is not provided, and the wafers W on the turntable 2 alternately pass through the first process area (film deposition area) P1 and the reformulation area S1 through the separating area D. Further, when the adsorption layer is deposited by adsorption of the component of the first process gas onto the surface of the wafer W in the first process area 21, the adsorption layer is thermally decomposed by heat generated by the heater unit 7 and impurities such as hydrogen and chlorine desorbs during the orbital rotation of the wafers W on the turntable 2. Accordingly, the reaction layer 301 is formed by a reaction of thermal decomposition of the adsorption layer.

However, because the turntable 2 rotates around the vertical axis, a time period until the wafer W reaches the reformulation area S1 after the wafer W on the turntable 2 passes through the first process area P1, namely a time period for ejecting the impurities from the adsorption layer, is extremely short.

Therefore, the impurities are still contained in the reaction layer 301 of the wafer 301 before reaching the reformulation area S1. Therefore, the impurities are removed from the reaction layer 301 by supplying plasma of, for example, an argon gas onto the wafer W. Thus, the reaction layer having a good film property is obtainable. Thus, by causing the wafer W to alternately pass through the areas P1 and S1, the reaction layer 301 is deposited as a multilayer to a silicon film. Therefore, “plasma reformulation process” in the embodiments of the present invention includes not only a process of removing the impurities from the reaction layer 301 to reformulate the reaction layer 301 but also a process of causing the adsorption layer to react (reaction of thermal decomposition).

As the plasma generating gas used for the plasma process of the silicon film is a gas of generating plasma for applying energy of ions to the wafer W. Specifically, this gas is a rare gas such as helium (He) gas or a hydrogen gas in addition to the above described argon gas.

In a case where the silicon film is formed, a material to be doped is used as the second process gas, and boron (B) or phosphor (P) may be doped onto the silicon film.

TABLE 7
AREA FOR RAW MATERIAL B
MATERIAL FOR DOPING Si

PH₃ (PHOSPHINE), B₂H₆
(DIBORANE), BCl₃

Further, a metal oxide film, a metal nitride film, a metal carbonate film, or a High-k film (high dielectric constant film) may be formed by using the gas made of a chemical compound listed in Table 8 as the first process gas and by using the above described second process gas.

TABLE 8
AREA FOR RAW MATERIAL A
MATERIAL FOR FORMING SiC

TMA (TRIMETHYLALUMINUM), Cu(hfac) TMVS
(HEXAFLUOROACETYLACETONE-
TRIMDIETHYLVINYLSILYLCOPPER), Cu (EDMDD)₂, TBTDET
(TERTIARYBUTYLIMIDE-TRI-DIETHYLAMIDOTANTALUM),
PET (TANTALUM PENTAETHOXIDE), TiCl₄
(TITANIUM(IV)CHLORIDE), AlCl₃ (ALUMINUM CHLORIDE),
TEH (TETRAKIS(ETHOXY)HAFNIUM), Zr (OtBt)₄, HTTB
(HAFNIUMTETRATERTIARYBUTOXIDE), TDMAH
(TETRAKIS(DIMETHYLAMINO)HAFNIUM), TDEAH
(TETRAKIS(DIETHYLAMINO)HAFNIUM), TEMAH
(TETRAKIS(ETHYLMETHYLAMINO)HAFNIUM), Hf
(MMP)₄(TETRAKIS(METHOXYMETHYLPROPOXY)HAFNIUM),
ZTTB (ZIRCONIUMTETRATERTIARYBUTOXIDE),
TDMAZ (TETRAKIS(DIMETHYLAMINO)ZIRCONIUM), TDEAZ
(TETRAKIS(DIETHYLAMINO)ZIRCONIUM), TEMAZ
(TETRAKIS(ETHYLMETHYLAMINO)ZIRCONIUM), Zr
(MMP)₄(TETRAKIS(METHOXYMETHYLPROPOXY)ZIRCONIUM),
TEA (TETRAETHYLALUMINUM),
Al (MMP)₃(TRIS(METHOXYMETHYLPROPOXY)ALUMINUM)

Further, a plasma ion implanting gas used along with a plasma reformulation gas or a plasma ion implanting gas used together with the plasma reformulation gas may be plasma of a gas made of a chemical compound listed in Table 9.

TABLE 9
SIDE OF PLASMA AREA
REFORMULATED PLASMA GAS
PLASMA ION IMPLANTING GAS

O₂ PLASMA, Ar PLASMA,
He PLASMA, H₂ PLASMA,
N₂ PLASMA,
NH₃ PLASMA, H₂O PLASMA,
CH₄ PLASMA
N₂O PLASMA
CO₂ PLASMA

Meanwhile, referring to Table 7, plasma containing oxygen (O), plasma containing nitrogen (N), and plasma containing carbon (C) may be used only for processes of depositing an oxide film, a nitride film, and a carbonized film.

Further, although the above described plasma reformulation process is performed every rotation of the turntable 2, namely every deposition of the reaction layer 301, the plasma reformulation process may be performed every lamination of, for example, 10 to 100 layers included in the reaction layer 301. In this case, power supply to the high-frequency power sources 85 and 128 is stopped at the time of starting to deposit the film. After the turntable 2 is rotated by the number of turns equal to the number of laminating the reaction layer 301, supply of the gases to the nozzles 31 and 32 is stopped and power is supplied to the high-frequency power sources 85 and 128 to thereby perform the plasma reformulation. Thereafter, lamination of the reaction layer 301 and the plasma reformulation are repeated again.

Furthermore, the plasma reformulation process may be performed for the wafer W, on which the thin film is already deposited. In this case, although the gas nozzles 31, 32, 41, and 42 are not provided inside the vacuum chamber 1, the plasma generating gas nozzle 34, the turntable 2, and the bias electrode 120, and so on are provided.

As described, even in a case where only the plasma reformulation process is performed inside the vacuum chamber 1, because plasma (ions) are lead inside the depressed portion 10 by the bias space S3, it is possible to uniformly perform a plasma reformulation process along the depth direction of the depressed portion 101.

Furthermore, the plasma process applied to the wafer W may be activation of the process gas instead of the reformulation. Specifically, the plasma process portion 80 is assembled to the above described second process gas nozzle 32 and the bias electrode 120 may be arranged on the lower side of the nozzle 32. In this case, the process gas (an oxygen gas) discharged from the nozzle 32 is activated in the plasma process portion 80 to thereby generated plasma, and the plasma is lead in the side of the wafer W. Therefore, it is possible to match the film thickness and the film property of the reaction layer 30 in the depth direction of the depressed portion 10.

As described, even when the process gas is changed to plasma, the above described plasma reformulation process may be simultaneously performed together with the change of the process gas to plasma. Further, the process of specifically change the process gas to plasma may be applied not only to a film deposition of the thin film of the above described Si—O group but also to, for example, the film deposition of the thin film of a silicon nitride (Si—N) group. In a case where the thin film of Si—N system is formed, a gas containing nitrogen (N) such as an ammonia (NH₃) gas may be used as the second process gas.

According to the embodiments of the present invention, when the plasma process is performed for the plurality of wafers W orbitally revolving around on the turntable 2, the bias electrode for leading the ions is arranged at a position facing the plasma generating area on the lower side of the turntable 2. Further, the bias electrode is formed so as to extend from the rotational center side of the turntable to the outer edge side and so that the width of the bias electrode is smaller than the distance between the substrate mounting portions in the rotational direction of the turntable. Therefore, it is possible to individually lead ions into the substrates while restricting a bias electric field from being simultaneously applied onto the substrates. Therefore, even if a depressed portion having a great aspect ratio is formed, a plasma process can be uniformly performed along the depth direction of the depressed portion and the degrees of the plasma process in the plurality of wafers can be matched. According to the substrate processing apparatus and the method of depositing a film of the embodiments of the present invention, the total time for a process of depositing the films on the plurality of substrates can be shortened by simultaneously perform the reformulation and an operation of carrying out the substrate.

All examples and conditional language recited herein are intended for pedagogical purposes to aid the reader in understanding the embodiments and the concepts contributed by the inventor to furthering the art, and are to be construed as being without limitation to such specifically recited examples and conditions, nor does the organization of such examples in the specification relate to a showing of superiority or inferiority of the embodiments. Although the film deposition apparatus and the method of depositing a film have been described in detail, it should be understood that the various changes, substitutions, and alterations could be made hereto without departing from the spirit and scope of the invention.

What is claimed is:

1. A substrate processing apparatus for performing a plasma process for substrates inside a vacuum chamber, the substrate processing apparatus comprising:
a turntable which includes substrate mounting portions for mounting the substrates formed at a plurality of positions along a peripheral direction of the vacuum chamber and causes the substrate mounting portions to orbitally revolve around;
a plasma generating gas supplying portion which supplies a plasma generating gas into a plasma generating area for performing the plasma process for the substrates;
an energy supplying portion which supplies energy to the plasma generating gas in order to change the plasma generating gas to plasma;
a bias electrode which is provided on a lower side of the turntable so as to face the plasma generating area and leads ions included in the plasma onto surfaces of the wafers; and
an evacuation port which evacuates an inside of the vacuum chamber,
wherein the bias electrode is formed so as to extend from a side of a rotational center of the turntable to an outer edge side of the turntable, and a width of the bias electrode in a rotational direction of the turntable is smaller than a distance between adjacent substrate mounting portions included in the substrate mounting portions.

2. The substrate processing apparatus according to claim 1, further comprising:
a process gas supplying portion which is positioned at a position separate from the plasma generating area in the rotational direction of the turntable, and supplies a process gas onto the substrate mounting portions to deposit thin films by sequentially laminating a molecular layer or an atomic layer on the substrate while rotating the turntable,
wherein the plasma generating area is provided to reformulate the molecular layer or the atomic layer.

3. The substrate processing apparatus according to claim 1, further comprising:
an opposing electrode which is arranged so as to face the bias electrode on an upper side of the turntable and is capacitively coupled with the bias electrode; and
a high-frequency power source which is provided to generate a bias potential on the substrates by supplying high frequency power to the bias electrode and the opposing electrode and causing the opposing electrode to be capacitively coupled with the bias electrode.

4. The substrate processing apparatus according to claim 1, further comprising:
a power source which generates, by electrostatic induction, the bias potential for causing the ions included in the plasma to be lead onto the surfaces of the substrates provided on the turntable.

5. The substrate processing apparatus according to claim 1,
wherein the energy supplying portion includes
an antenna which is wound around a vertical axis and generates induction coupling plasma as the plasma in the plasma generating area, and
a high-frequency power source which is connected with the antenna and generates the plasma,
wherein the opposing electrode is located between the antenna and the plasma generating area, and is a conductive plate having a plurality of slits for cutting off an electric field included in an electromagnetic field formed by the antenna and causing a magnetic field included in the electromagnetic field to pass, the slits being arranged along a periphery of the antenna so as to intersect with a peripheral direction of the antenna.

6. The substrate processing apparatus according to claim 1,
wherein the energy supplying portion includes a pair of electrodes arranged to face each other in order to generate a capacitively coupling plasma as the plasma in the plasma generating area.

7. The substrate processing apparatus according to claim 1,
wherein a number of the substrate mounting portions formed on the turntable is four or greater, and
a distance between the adjacent substrate mounting portions is equal to and greater than 30 mm and equal to and less than 120 mm

8. The substrate processing apparatus according to claim 1, further comprising:
a lifting mechanism which lifts the bias electrode up and down.

9. A method of depositing a film by performing a process of depositing the film onto substrates inside a vacuum chamber, the method of depositing the film comprising:
mounting the substrates on substrate mounting portions formed on the turntable at a plurality of positions along a peripheral direction of the vacuum chamber, surfaces of the substrates being formed with a depressed portion;
orbitally revolving the substrate mounting portions around;
depositing a molecular layer or an atomic layer on the substrates by supplying a process gas onto the substrates provided on the substrate mounting portions;
reformulating the molecular layer or the atomic layer using plasma by supplying a plasma generating gas into a plasma generating area inside the vacuum chamber and changing the plasma generating gas to the plasma;
leading ions included in the plasma onto the surfaces of the substrates using a bias electrode located on a lower side of the turntable so as to face the plasma generating area; and
evacuating an inside of the vacuum chamber,
wherein the bias electrode, used in the leading the ions, is formed so as to extend from a side of a rotational center of the turntable to an outer edge side of the turntable, and a width of the bias electrode in a rotational direction of the turntable is smaller than a distance between adjacent substrate mounting portions included in the substrate mounting portions.
